(19) United States
(12) Patent Application Publication
(10) Pub. No.: US 2026/0361315 A1
(43) Pub. Date: Nov. 12, 2026

(54) APPARATUS, SYSTEM, AND METHOD OF CONVERTING A DIGITAL SIGNAL INTO AN ANALOG SIGNAL

(71) Applicant: MobilEye Vision Technologies Ltd., Jerusalem (IL)

(72) Inventor: Uzi HIZI, Herzliya (IL)

(73) Assignee: MobilEye Vision Technologies Ltd., Jerusalem (IL)

(21) Appl. No.: 19/491,285

(22) PCT Filed: May 28, 2024
(86) PCT No.: PCT/IB2024/055186

§ 371 Date: Dec. 8, 2025

(51) Int. Cl. H03M 1/74; H03M 1/68

(52) U.S. Cl. CPC H03M 1/74; H03M 1/685

(57) ABSTRACT

For example, a current-steering Digital to Analog Converter (DAC) may be configured to convert a digital signal into an analog signal. For example, the current-steering DAC may include a thermometer-decoded current-steering DAC including a two-dimensional (2D) array of current-steering cells. For example, the 2D array may include a plurality of first-dimension subarrays and a plurality of second-dimension subarrays. For example, a current-steering cell of the 2D array may be switchable between a first steering state to steer a current of the current-steering cell to a first current path, a second steering state to steer the current of the current-steering cell to a second current path, and a third steering state to steer the current of the current-steering cell to a switch path of a plurality of switch paths corresponding to the plurality of second-dimension subarrays.

### BACKGROUND

A Digital To Analog Converter (DAC) may be configured to convert digital signals into analog signals.

There are various types/architectures of DACs, which may be suitable for various applications.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of a vehicle implementing a light-based sensor, in accordance with some demonstrative aspects.

FIG. 2 is a schematic block diagram illustration of a robot implementing a light-based sensor, in accordance with some demonstrative aspects.

FIG. 3 is a schematic block diagram illustration of a light-based sensor apparatus, in accordance with some demonstrative aspects.

FIG. 4 is a schematic illustration of a light-based sensor, in accordance with some demonstrative aspects.

FIG. 5 is a schematic illustration of a Digital to Analog Converter (DAC), in accordance with some demonstrative aspects.

FIG. 6A, is a schematic illustration of a current-steering DAC, and FIG. 6B is a schematic illustration of a current-steering cell and a switch cell of the current-steering DAC, in accordance with some demonstrative aspects.

FIG. 7 is a schematic illustration of a thermometer-decoded current-steering DAC, in accordance with some demonstrative aspects.

FIG. 8 is a schematic flow-chart illustration of a method of converting a digital signal into an analog signal, in accordance with some demonstrative aspects.

FIG. 9 is a schematic illustration of a product of manufacture, in accordance with some demonstrative aspects.

### DETAILED DESCRIPTION

In the following detailed description, numerous specific details are set forth in order to provide a thorough understanding of some aspects. However, it will be understood by persons of ordinary skill in the art that some aspects may be practiced without these specific details. In other instances, well-known methods, procedures, components, units and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

The words “exemplary” and “demonstrative” are used herein to mean “serving as an example, instance, demonstration, or illustration”. Any aspect, or design described herein as “exemplary” or “demonstrative” is not necessarily to be construed as preferred or advantageous over other aspects, or designs.

References to “one aspect”, “an aspect”, “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

The phrases “at least one” and “one or more” may be understood to include a numerical quantity greater than or equal to one, e.g., one, two, three, four, [. . . ] , etc. The phrase “at least one of” with regard to a group of elements may be used herein to mean at least one element from the group consisting of the elements. For example, the phrase “at least one of” with regard to a group of elements may be used herein to mean one of the listed elements, a plurality of one of the listed elements, a plurality of individual listed elements, or a plurality of a multiple of individual listed elements.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and/or may represent any information as understood in the art.

The terms “processor” or “controller” may be understood to include any kind of technological entity that allows handling of any suitable type of data and/or information. The data and/or information may be handled according to one or more specific functions executed by the processor or controller. Further, a processor or a controller may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), and the like, or any combination thereof. Any other kind of implementation of the respective functions, which will be described below in further detail, may also be understood as a processor, controller, or logic circuit. It is understood that any two (or more) processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” is understood as a computer-readable medium (e.g., a non-transitory computer-readable medium) in which data or information can be stored for retrieval. References to “memory” may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” may be used to refer to any type of executable instruction and/or logic, including firmware.

A “vehicle” may be understood to include any type of driven object. By way of example, a vehicle may be a driven object with a combustion engine, an electric engine, a reaction engine, an electrically driven object, a hybrid driven object, or a combination thereof. A vehicle may be, or may include, an automobile, a bus, a mini bus, a van, a truck, a mobile home, a vehicle trailer, a motorcycle, a bicycle, a tricycle, a train locomotive, a train wagon, a moving robot, a personal transporter, a boat, a ship, a submersible, a submarine, a drone, an aircraft, a rocket, among others.

A “ground vehicle” may be understood to include any type of vehicle, which is configured to traverse the ground, e.g., on a street, on a road, on a track, on one or more rails, off-road, or the like.

An “autonomous vehicle” may describe a vehicle capable of implementing at least one navigational change without driver input. A navigational change may describe or include a change in one or more of steering, braking, acceleration/deceleration, or any other operation relating to movement, of the vehicle. A vehicle may be described as autonomous even in case the vehicle is not fully autonomous, for example, fully operational with driver or without driver input. Autonomous vehicles may include those vehicles that can operate under driver control during certain time periods, and without driver control during other time periods. Additionally or alternatively, autonomous vehicles may include vehicles that control only some aspects of vehicle navigation, such as steering, e.g., to maintain a vehicle course between vehicle lane constraints, or some steering operations under certain circumstances, e.g., not under all circumstances, but may leave other aspects of vehicle navigation to the driver, e.g., braking or braking under certain circumstances. Additionally or alternatively, autonomous vehicles may include vehicles that share the control of one or more aspects of vehicle navigation under certain circumstances, e.g., hands-on, such as responsive to a driver input; and/or vehicles that control one or more aspects of vehicle navigation under certain circumstances, e.g., hands-off, such as independent of driver input. Additionally or alternatively, autonomous vehicles may include vehicles that control one or more aspects of vehicle navigation under certain circumstances, such as under certain environmental conditions, e.g., spatial areas, roadway conditions, or the like. In some aspects, autonomous vehicles may handle some or all aspects of braking, speed control, velocity control, steering, and/or any other additional operations, of the vehicle. An autonomous vehicle may include those vehicles that can operate without a driver. The level of autonomy of a vehicle may be described or determined by the Society of Automotive Engineers (SAE) level of the vehicle, e.g., as defined by the SAE, for example in SAE J3016 2018: Taxonomy and definitions for terms related to driving automation systems for on road motor vehicles, or by other relevant professional organizations. The SAE level may have a value ranging from a minimum level, e.g., level 0 (illustratively, substantially no driving automation), to a maximum level, e.g., level 5 (illustratively, full driving automation).

An “assisted vehicle” may describe a vehicle capable of informing a driver or occupant of the vehicle of sensed data or information derived therefrom.

The phrase “vehicle operation data” may be understood to describe any type of feature related to the operation of a vehicle. By way of example, “vehicle operation data” may describe the status of the vehicle, such as, the type of tires of the vehicle, the type of vehicle, and/or the age of the manufacturing of the vehicle. More generally, “vehicle operation data” may describe or include static features or static vehicle operation data (illustratively, features or data not changing over time). As another example, additionally or alternatively, “vehicle operation data” may describe or include features changing during the operation of the vehicle, for example, environmental conditions, such as weather conditions or road conditions during the operation of the vehicle, fuel levels, fluid levels, operational parameters of the driving source of the vehicle, or the like. More generally, “vehicle operation data” may describe or include varying features or varying vehicle operation data (illustratively, time varying features or data).

Some aspects may be used in conjunction with various devices and systems, for example, a light-based sensor, a light-based sensor device, a light-based sensor system, a vehicle, a vehicular system, an autonomous vehicular system, a vehicular communication system, a vehicular device, an airborne platform, a waterborne platform, road infrastructure, sports-capture infrastructure, city monitoring infrastructure, static infrastructure platforms, indoor platforms, moving platforms, robot platforms, industrial platforms, a sensor device, a User Equipment (UE), a Mobile Device (MD), a wireless station (STA), a sensor device, a non-vehicular device, a mobile or portable device, and the like.

Some aspects may be used in conjunction with light-based sensor systems, vehicular light-based sensor systems, Light Detection And Ranging (LiDAR) systems, vehicular sensor systems, autonomous systems, robotic systems, detection systems, or the like.

As used herein, the term “circuitry” may refer to, be part of, or include, an Application Specific Integrated Circuit (ASIC), an integrated circuit, an electronic circuit, a processor (shared, dedicated, or group), and/or memory (shared, dedicated, or group), that execute one or more software or firmware programs, a combinational logic circuit, and/or other suitable hardware components that provide the described functionality. In some aspects, some functions associated with the circuitry may be implemented by one or more software or firmware modules. In some aspects, circuitry may include logic, at least partially operable in hardware.

The term “logic” may refer, for example, to computing logic embedded in circuitry of a computing apparatus and/or computing logic stored in a memory of a computing apparatus. For example, the logic may be accessible by a processor of the computing apparatus to execute the computing logic to perform computing functions and/or operations. In one example, logic may be embedded in various types of memory and/or firmware, e.g., silicon blocks of various chips and/or processors. Logic may be included in, and/or implemented as part of, various circuitry, e.g., radio circuitry, receiver circuitry, control circuitry, transmitter circuitry, transceiver circuitry, processor circuitry, and/or the like. In one example, logic may be embedded in volatile memory and/or non-volatile memory, including random access memory, read only memory, programmable memory, magnetic memory, flash memory, persistent memory, and/or the like. Logic may be executed by one or more processors using memory, e.g., registers, buffers, stacks, and the like, coupled to the one or more processors, e.g., as necessary to execute the logic.

The term “communicating” as used herein with respect to a signal includes transmitting and/or emitting the signal, and/or receiving and/or detecting the signal. For example, a communication unit, which is capable of communicating a signal, may include a transmitter and/or emitter to transmit and/or emit the signal, and/or a receiver and/or detector to receive and/or detect a signal. The verb communicating may be used to refer to the action of transmitting/emitting or the action of receiving/detecting. In one example, the phrase “communicating a transmission signal” may refer to the action of transmitting/emitting the signal by a first device, and may not necessarily include the action of receiving/detecting the signal by a second device. In another example, the phrase “communicating a transmission signal” may refer to the action of receiving/detecting the signal by a first device, and may not necessarily include the action of transmitting/emitting the signal by a second device.

For example, the term “communicating” as used herein with respect to a light signal includes transmitting and/or emitting the light signal, and/or receiving and/or detecting the light signal. For example, a communication unit, which is capable of communicating a light signal, may include an emitter to emit the light signal, and/or a detector to detect and/or receive the light signal. The verb communicating may be used to refer to the action of transmitting/emitting or the action of receiving/detecting. In one example, the phrase “communicating a light signal” may refer to the action of transmitting/emitting the signal by a first device, and may not necessarily include the action of receiving/detecting the light signal by a second device. In another example, the phrase “communicating a light signal” may refer to the action of receiving/detecting the light signal by a first device, and may not necessarily include the action of transmitting/emitting the light signal by a second device.

Some demonstrative aspects are described herein with respect to light-based systems, for example, utilizing light-based sensors, e.g., Light Detection And Ranging (LiDAR) systems, utilizing light signals. However, other aspects may be implemented with respect to, or in conjunction with, any other signals, e.g., radar signals, sonar systems, wireless signals, IR signals, acoustic signals, optical signals, wireless communication signals, communication scheme, network, standard, and/or protocol.

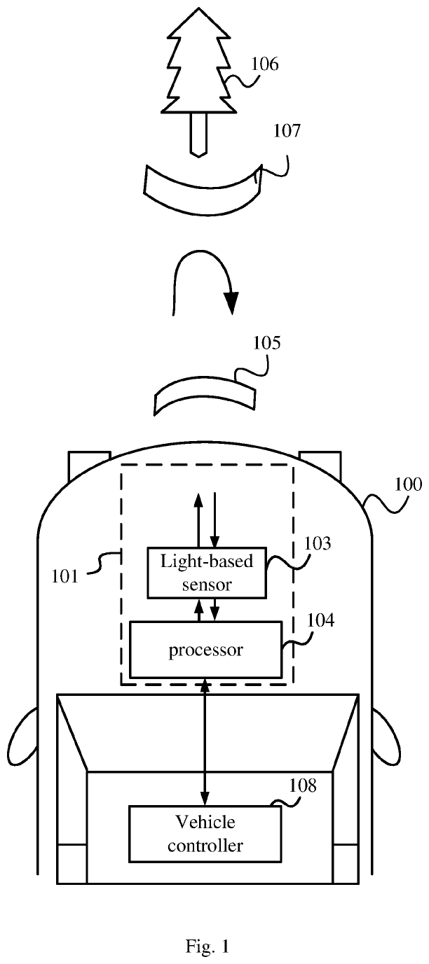

Reference is now made to FIG. 1, which schematically illustrates a block diagram of a vehicle 100 implementing a light-based sensor, in accordance with some demonstrative aspects.

In some demonstrative aspects, vehicle 100 may include a car, a truck, a motorcycle, a bus, a train, an airborne vehicle, a waterborne vehicle, a cart, a golf cart, an electric cart, a road agent, or any other vehicle.

In some demonstrative aspects, vehicle 100 may include a light-based sensor device 101, e.g., as described below. For example, light-based sensor device 101 may include a light-based sensor detecting device, a light-based sensing device, a light-based sensor, or the like, e.g., as described below.

In some demonstrative aspects, light-based sensor device 101 may include a Light Detection and Ranging (LiDAR) sensor device.

In some demonstrative aspects, light-based sensor device 101 may include a Frequency Modulated Continuous Wave (FMCW) LiDAR sensor device, e.g., as described below.

In other aspects, light-based sensor device 101 may include any other suitable type of light-based sensor device.

In some demonstrative aspects, light-based sensor device 101 may be implemented as part of a vehicular system, for example, a system to be implemented and/or mounted in vehicle 100.

In one example, light-based sensor device 101 may be implemented as part of an autonomous vehicle system, an automated driving system, an assisted vehicle system, a driver assistance and/or support system, and/or the like.

For example, light-based sensor device 101 may be installed in vehicle 100 for detection of nearby objects, e.g., for autonomous driving.

In some demonstrative aspects, light-based sensor device 101 may be configured to detect targets in a vicinity of vehicle 100, e.g., in a far vicinity and/or a near vicinity, for example, using light waves and/or signals, e.g., as described below.

In one example, light-based sensor device 101 may be mounted onto, placed, e.g., directly, onto, or attached to, vehicle 100.

In some demonstrative aspects, vehicle 100 may include a plurality of light-based sensor devices 101. In other aspects, vehicle 100 may include a single light-based sensor device 101.

In some demonstrative aspects, vehicle 100 may include a plurality of light-based sensor devices 101, which may be configured to cover a field of view of 360 degrees around vehicle 100.

In other aspects, vehicle 100 may include any other suitable count, arrangement, and/or configuration of light-based sensor devices and/or units, which may be suitable to cover any other field of view, e.g., a field of view of less than 360 degrees.

In some demonstrative aspects, light-based sensor device 101 may be implemented as a component in a suite of sensors used for driver assistance and/or autonomous vehicles.

In some demonstrative aspects, light-based sensor device 101 may be configured to support autonomous vehicle usage, e.g., as described below.

In one example, light-based sensor device 101 may determine a class, a location, a distance, a range, an orientation, a velocity, an intention, a perceptional understanding of the environment, and/or any other information corresponding to an object in the environment.

In another example, light-based sensor device 101 may be configured to determine one or more parameters and/or information for one or more operations and/or tasks, e.g., path planning, and/or any other tasks.

In some demonstrative aspects, light-based sensor device 101 may be configured to map a scene by measuring targets' reflectivity and discriminating them, for example, mainly in range, velocity, azimuth and/or elevation, e.g., as described below.

In some demonstrative aspects, light-based sensor device 101 may be configured to detect, and/or sense, one or more objects, which are located in a vicinity, e.g., a far vicinity and/or a near vicinity, of the vehicle 100, and to provide one or more parameters, attributes, and/or information with respect to the objects.

In some demonstrative aspects, the objects may include road users, such as other vehicles, pedestrians; road objects and markings, such as traffic signs, traffic lights, lane markings, road markings, road elements, e.g., a pavement-road meeting, a road edge, a road profile, road roughness (or smoothness); general objects, such as a hazard, e.g., a tire, a box, a crack in the road surface; and/or the like.

In some demonstrative aspects, the one or more parameters, attributes and/or information with respect to the object may include a range of the objects from the vehicle 100, an angle of the object with respect to the vehicle 100, a location of the object with respect to the vehicle 100, a relative speed of the object with respect to vehicle 100, and/or the like.

In some demonstrative aspects, light-based sensor device 101 may include a light-based sensor 103 configured to communicate light signals, e.g., as described below.

In some demonstrative aspects, light-based sensor device 101 may include a processor 104, which may be configured to generate light-based sensor information based on the light signals, e.g., as described below.

In some demonstrative aspects, processor 104 may be configured to process the light-based sensor information of light-based sensor device 101 and/or to control one or more operations of light-based sensor device 101, e.g., as described below.

In some demonstrative aspects, processor 104 may include, or may be implemented, partially or entirely, by circuitry and/or logic, e.g., one or more processors including circuitry and/or logic, memory circuitry and/or logic. Additionally or alternatively, one or more functionalities of processor 104 may be implemented by logic, which may be executed by a machine and/or one or more processors, e.g., as described below.

In one example, processor 104 may include at least one memory, e.g., coupled to the one or more processors, which may be configured, for example, to store, e.g., at least temporarily, at least some of the information processed by the one or more processors and/or circuitry, and/or which may be configured to store logic to be utilized by the processors and/or circuitry.

In other aspects, processor 104 may be implemented by one or more additional or alternative elements of vehicle 100.

In some demonstrative aspects, light-based sensor 103 may include a LiDAR sensor, e.g., as described below.

In some demonstrative aspects, light-based sensor 103 may include an FMCW LiDAR sensor, e.g., as described below.

In other aspects, light-based sensor 103 may include any other additional type of light-based sensor configured to generate light-based sensor information based on sensed and/or detected light.

In some demonstrative aspects, light-based sensor 103 may include, for example, one or more light transmitters, and/or a one or more light receivers/detectors, e.g., as described below.

In some demonstrative aspects, as shown in FIG. 1, the light-based sensor 103 may be controlled, e.g., by processor 104, to transmit a light signal 105.

In some demonstrative aspects, as shown in FIG. 1, the light signal 105 may be reflected by an object 106, resulting in reflected light 107.

In some demonstrative aspects, the light-based sensor device 101 may receive the reflected light 107, e.g., via light-based sensor 103, and processor 104 may generate sensor information, for example, by calculating information about position, radial velocity, and/or direction of the object 106, e.g., with respect to vehicle 100.

In some demonstrative aspects, processor 104 may be configured to provide the sensor information to a vehicle controller 108 of the vehicle 100, e.g., for autonomous driving of the vehicle 100.

In some demonstrative aspects, at least part of the functionality of processor 104 may be implemented as part of vehicle controller 108. In other aspects, the functionality of processor 104 may be implemented as part of any other element of light-based sensor device 101 and/or vehicle 100. In other aspects, processor 104 may be implemented, as a separate part of, or as part of any other element of light-based sensor device 101 and/or vehicle 100.

In some demonstrative aspects, vehicle controller 108 may be configured to control one or more functionalities, modes of operation, components, devices, systems and/or elements of vehicle 100.

In some demonstrative aspects, vehicle controller 108 may be configured to control one or more vehicular systems of vehicle 100, e.g., as described below.

In some demonstrative aspects, the vehicular systems may include, for example, a user interface, a steering system, a braking system, a driving system, and/or any other system of the vehicle 100.

In some demonstrative aspects, vehicle controller 108 may configured to control light-based sensor device 101, and/or to process one or parameters, attributes and/or information from light-based sensor device 101.

In some demonstrative aspects, vehicle controller 108 may be configured, for example, to control the vehicular systems of the vehicle 100, for example, based on the sensor information from light-based sensor device 101 and/or one or more other sensors of the vehicle 100, e.g., radar sensors, camera sensors, and/or the like.

In one example, vehicle controller 108 may control the user interface, the steering system, the braking system, and/or any other vehicular systems of vehicle 100, for example, based on the information from light-based sensor device 101, e.g., based on one or more objects detected by light-based sensor device 101.

In other aspects, vehicle controller 108 may be configured to control any other additional or alternative functionalities of vehicle 100.

Some demonstrative aspects are described herein with respect to a light-based sensor device 101 implemented in a vehicle, e.g., vehicle 100.

In other aspects a light-based sensor device, e.g., light-based sensor device 101, may be implemented as part of any other element of a traffic system or network, for example, as part of a road infrastructure, and/or any other element of a traffic network or system. Other aspects may be implemented with respect to any other system, environment, and/or apparatus, which may be implemented in any other object, environment, location, or place.

In one example, light-based sensor device 101 may be part of a non-vehicular device, which may be implemented, for example, in an indoor location, a stationary infrastructure outdoors, or any other location.

In another example, light-based sensor device 101 may be part of a mobile or non-mobile device. For example, light-based sensor device 101 may be implemented as part of a smartphone, a tablet, a computing device, or the like.

In another example, light-based sensor device 101 may be part of an optical device. For example, light-based sensor device 101 may be implemented as part of a camera, a spectrometer, a microscope, or the like.

In some demonstrative aspects, light-based sensor device 101 may be configured to support security usage. In one example, light-based sensor device 101 may be configured to determine a nature of an operation, e.g., a human entry, an animal entry, an environmental movement, and the like, to identity a threat level of a detected event, and/or any other additional or alternative operations.

Some demonstrative aspects may be implemented with respect to any other additional or alternative devices and/or systems, for example, for a robot, e.g., as described below.

In other aspects, light-based sensor device 101 may be configured to support any other usages and/or applications.

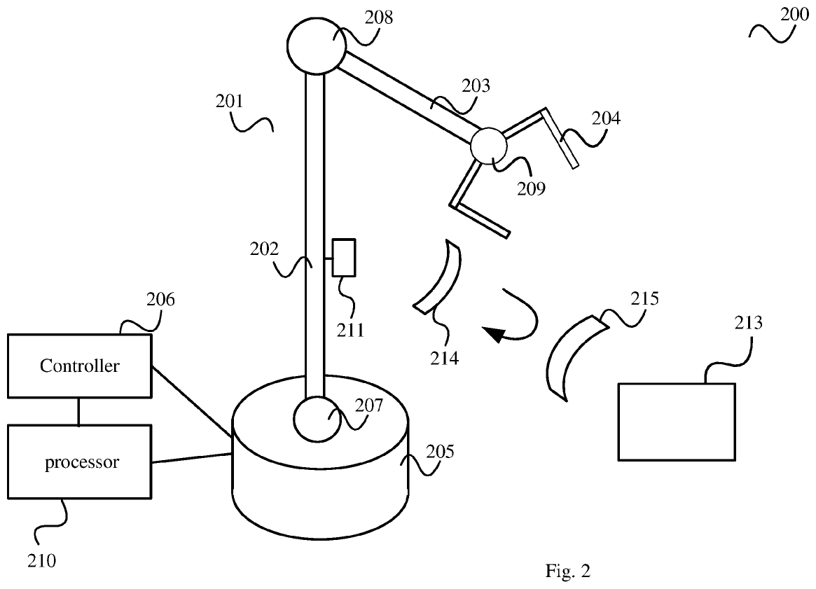

Reference is now made to FIG. 2, which schematically illustrates a block diagram of a robot 200 implementing a light-based sensor 211, in accordance with some demonstrative aspects.

In some demonstrative aspects, robot 200 may include a robot arm 201. The robot 200 may be implemented, for example, in a factory for handling an object 213, which may be, for example, a part that should be affixed to a product that is being manufactured. The robot arm 201 may include a plurality of movable members, for example, movable members 202, 203, 204, and a support 205. Moving the movable members 202, 203, and/or 204 of the robot arm 201, e.g., by actuation of associated motors, may allow physical interaction with the environment to carry out a task, e.g., handling the object 213.

In some demonstrative aspects, the robot arm 201 may include a plurality of joint elements, e.g., joint elements 207, 208, 209, which may connect, for example, the members 202, 203, and/or 204 with each other, and with the support 205. For example, a joint element 207, 208, 209 may have one or more joints, each of which may provide rotatable motion, e.g., rotational motion, and/or translatory motion, e.g., displacement, to associated members and/or motion of members relative to each other. The movement of the members 202, 203, 204 may be initiated by suitable actuators.

In some demonstrative aspects, the member furthest from the support 205, e.g., member 204, may also be referred to as the end-effector 204 and may include one or more tools, such as, a claw for gripping an object, a welding tool, or the like. Other members, e.g., members 202, 203, closer to the support 205, may be utilized to change the position of the end-effector 204, e.g., in three-dimensional space. For example, the robot arm 201 may be configured to function similarly to a human arm, e.g., possibly with a tool at its end.

In some demonstrative aspects, robot 200 may include a (robot) controller 206 configured to implement interaction with the environment, e.g., by controlling the robot arm's actuators, according to a control program, for example, in order to control the robot arm 201 according to the task to be performed.

In some demonstrative aspects, an actuator may include a component adapted to affect a mechanism or process in response to being driven. The actuator can respond to commands given by the controller 206 (the so-called activation) by performing mechanical movement. This means that an actuator, typically a motor (or electromechanical converter), may be configured to convert electrical energy into mechanical energy when it is activated (i.e., actuated).

In some demonstrative aspects, controller 206 may be in communication with a processor 210 of the robot 200.

In some demonstrative aspects, light-based sensor 211 may be coupled to the processor 210. In one example, light-based sensor 211 may be included, for example, as part of the robot arm 201.

In some demonstrative aspects, the light-based sensor 211, and the processor 210 may be operable as, and/or may be configured to form, a light-based sensor device. For example, light-based sensor 211 may be configured to perform one or more functionalities of light-based sensor 103 (FIG. 1), and/or processor 210 may be configured to perform one or more functionalities of processor 104 (FIG. 1), e.g., as described above.

In some demonstrative aspects, light-based sensor 211 may include a LiDAR sensor, e.g., as described below.

In some demonstrative aspects, light-based sensor 211 may include an FMCW LiDAR sensor, e.g., as described below.

In other aspects, light-based sensor 211 may include any other additional type of light-based sensor configured to generate light-based sensor information based on sensed and/or detected light.

In some demonstrative aspects, for example, the light-based sensor 211 may be controlled, e.g., by processor 210, to transmit a light signal 214.

In some demonstrative aspects, as shown in FIG. 2, the light signal 214 may be reflected by the object 213, resulting in reflected light 215.

In some demonstrative aspects, the reflected light 215 may be received, e.g., via light-based sensor 211, and processor 210 may generate sensor information, for example, by calculating information about position, speed and/or direction of the object 213, e.g., with respect to robot arm 201.

In some demonstrative aspects, processor 210 may be configured to provide the sensor information to the robot controller 206 of the robot arm 201, e.g., to control robot arm 201. For example, robot controller 206 may be configured to control robot arm 201 based on the sensor information, e.g., to grab the object 213 and/or to perform any other operation.

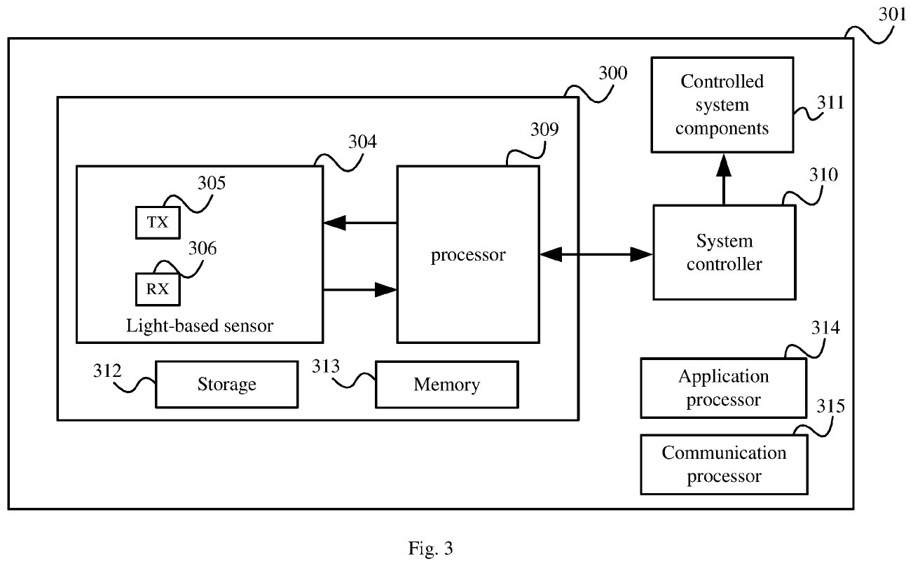

Reference is made to FIG. 3, which schematically illustrates a light-based sensor apparatus 300, in accordance with some demonstrative aspects.

In some demonstrative aspects, light-based sensor apparatus 300 may be implemented as part of a device or system 301, e.g., as described below.

For example, light-based sensor apparatus 300 may be implemented as part of, and/or may configured to perform one or more operations and/or functionalities of, the devices or systems described above with reference to FIG. 1 an/or FIG. 2. In other aspects, light-based sensor apparatus 300 may be implemented as part of any other device or system 301. For example, light-based sensor device 103 (FIG. 1), and/or light-based sensor 211 (FIG. 2), may include one or more elements of light-based sensor apparatus 300, and/or may perform one or more operations and/or functionalities of light-based sensor apparatus 300.

In some demonstrative aspects, light-based sensor device 300 may include a light-based sensor 304.

In some demonstrative aspects, light-based sensor 304 may include a LiDAR sensor, e.g., as described below.

In some demonstrative aspects, light-based sensor 304 may include an FMCW LiDAR sensor, e.g., as described below.

In other aspects, light-based sensor 304 may include any other additional type of light-based sensor configured to generate light-based sensor information based on sensed and/or detected light.

In some demonstrative aspects, as shown in FIG. 3, light-based sensor 304 may include a light transmitter 305 and a light receiver 306, e.g., as described below.

In some demonstrative aspects, light transmitter 305 may include one or more elements, for example, a light source, optic elements, and/or one or more other elements, configured to generate light signals to be emitted by the light-based sensor 304.

In some demonstrative aspects, light-based sensor device 300 may include a processor 309.

In some demonstrative aspects, for example, processor 309 may provide digital transmit data values to the light-based sensor 304.

In some demonstrative aspects, receiver 306 may include one or more elements, for example, one or more photo detectors, one or optical elements and/or one or more other elements, configured to detect and/or process, light signals received by light receiver 306.

In some demonstrative aspects, for example, light receiver 306 may be configured to convert a detected light signal into digital reception data values based on the detected light. For example, light-based sensor 304 may provide the digital reception data values to the processor 309.

In some demonstrative aspects, processor 309 may be configured to process the digital reception data values, for example, to detect one or more objects, e.g., in an environment of the device/system 301. This detection may include, for example, the determination of information including one or more of range, speed, direction, and/or any other information, of one or more objects, e.g., with respect to the system 301.

In some demonstrative aspects, processor 309 may be configured to provide the determined sensor information to a system controller 310 of device/system 301. For example, system controller 310 may include a vehicle controller, e.g., if device/system 301 includes a vehicular device/system, a robot controller, e.g., if device/system 301 includes a robot device/system, or any other type of controller for any other type of device/system 301.

In some demonstrative aspects, the determined sensor information from processor 309 may be processed, e.g., by system controller 310 and/or any other element of system 301, for example, in combination with information from one or more other information sources, for example, radar information from a radar processor, vision information from a vision-based processor, or the like.

In some demonstrative aspects, an environmental model of an environment of system 301 may be determined, e.g., by system controller 310 and/or any other element of system 301, for example, based on the determined sensor information from processor 309, and/or the information from one or more other of information sources.

In some demonstrative aspects, a driving policy system, e.g., which may be implemented by system controller 310 and/or any other element of system 301, may process the environmental model, for example, to decide on one or more actions, which may be taken.

In some demonstrative aspects, system controller 310 may be configured to control one or more controlled system components 311 of the system 301, e.g., a motor, a brake, a steering system, and the like, e.g., by one or more corresponding actuators, for example, based on the one or more action decisions.

In some demonstrative aspects, light-based sensor device 300 may include a storage 312 and/or a memory 313, e.g., to store information processed by apparatus 300, for example, digital reception data values being processed by the processor 309, sensor information generated by processor 309, and/or any other data to be processed by processor 309.

In some demonstrative aspects, device/system 301 may include, for example, an application processor 314 and/or a communication processor 315, for example, to at least partially implement one or more functionalities of system controller 310 and/or to perform communication between system controller 310, light-based sensor device 300, the controlled system components 311, and/or one or more additional elements of device/system 301.

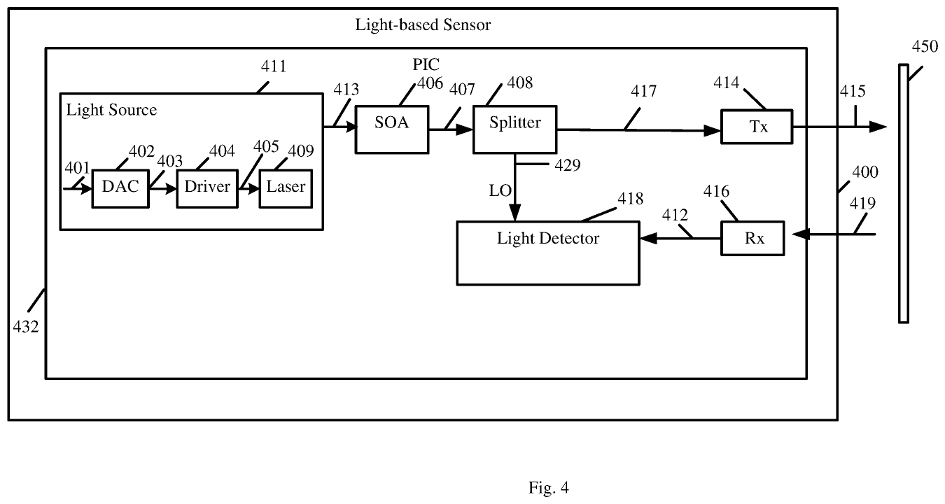

Reference is made to FIG. 4, which schematically illustrates a light-based sensor 400, in accordance with some demonstrative aspects.

For example, light-based sensor device 103 (FIG. 1), light-based sensor 211 (FIG. 2), and/or light-based sensor 304 (FIG. 3), may include one or more elements of light-based sensor 400, and/or may perform one or more operations and/or functionalities of light-based sensor 400.

In some demonstrative aspects, light based sensor 400 may include a LiDAR sensor.

In some demonstrative aspects, light based sensor 400 may include an FMCW LiDAR sensor.

In other aspects, light-based sensor 410 may include any other additional or alternative type light-based sensor, which may be configured to generate sensor information, for example, based on light transmitted and/or received by light-based sensor 410.

In some demonstrative aspects, light based sensor 400 may include a Photonics Integrated Circuit (PIC) 432.

In some demonstrative aspects, PIC 432 may be formed on a semiconductor substrate e.g., a silicon-based substrate.

In some demonstrative aspects, light based sensor 400 may include an optical Tx interface 414, which may be configured to emit an emitted light 415, e.g., a laser light. For example, light transmitter 305 (FIG. 3) may include one or more elements of optical Tx interface 414, and/or may perform one or more operations and/or functionalities of optical Tx interface 414.

In some demonstrative aspects, light based sensor 400 may include one or more optical components 450, which may be configured to direct the laser light towards a specific direction, or a target. For example, the one or more optical components 450 may include a scan mirror.

In one example, optical Tx interface 414 may include one or more lens, and/or grating structures, which may be configured to guide the laser light from the optical Tx interface 414 to the one or more optical components 450.

In some demonstrative aspects, light based sensor 400 may include an optical Rx interface 416, which may be configured to receive reflections 419 of the emitted light 415, which may be reflected from a target. For example, light receiver 306 (FIG. 3) may include one or more elements of optical Rx interface 416, and/or may perform one or more operations and/or functionalities of optical Rx interface 416.

In some demonstrative aspects, light-based sensor 410 may include a light detector 418, which may be configured to detect received light 412 via the optical Rx interface 418.

In some demonstrative aspects, the received light 412 may be based on the reflections 419 of the emitted light 415 from the target.

In one example, optical Rx interface 416 may include one or more lens, and/or one or more grating structures, which may be configured to guide the reflections 419 of the emitted light 415 from the or more optical components 450 to the light detector 418.

In one example, the optical Rx interface 416 and/or the optical Tx interface 414 may include one or more of a converging lens, a collimating lens, a diverging lens, or any other type of lens.

In one example, the optical Rx interface 416 and/or the optical Tx interface 414 may include one or more of a transmission grating, a reflective grating, a grism, and/or any other type of grating structures.

In some demonstrative aspects, light based sensor 400 may include at least one light source 411, which may be configured to provide a light output 413.

In some demonstrative aspects, as shown in FIG. 4, light-based sensor 400 may include a Digital to Analog Converter (DAC) 402, which may be configured to generate an analog signal 403, for example, based on a digital input signal 401.

In some demonstrative aspects, the digital signal input signal 401 may be provided, for example, by a processor, e.g., processor 309 (FIG. 3), or by any other element of light-based sensor 400.

In some demonstrative aspects, the analog signal 403 may be represented as a current signal or as a voltage signal.

In some demonstrative aspects, as shown in FIG. 4, DAC 402 may be implemented as part of light source 411.

In some demonstrative aspects, light source 411 may include a laser driver 404, which may be configured to generate a laser driving signal 405, for example, based on the analog signal 403.

In some demonstrative aspects, light output 413 from the light source 411 may be based on the laser driving signal 405. For example, light source 411 may include a laser source 409, which may be configured to generate the light output 413 based on the laser driving signal 405.

In some demonstrative aspects, DAC 402 may be implemented part of any other additional or alternative element of light-based sensor 400.

In some demonstrative aspects, DAC 402 may be configured to filter the analog signal 403, for example, to a certain bandwidth (BW), e.g., for reduction of noise.

In some demonstrative aspects, the emitted light 415 emitted by the optical Tx interface 414 may be based on the light output 413 from the light source 411.

In some demonstrative aspects, light-based sensor 400 may include an optical amplifier, e.g., a Silicon Optical Amplifier (SOA) 406 and/or any other type of optical amplifier, which may be configured to provide amplified light 407, for example, by amplifying the light output 413 from the light source 411.

In some demonstrative aspects, light based sensor 400 may include a splitter 408, which may be configured to split the amplified light 407 into a first amplified light 417 and a second amplified light 429.

In some demonstrative aspects, the first amplified light 417 may be used as input light to the optical Tx interface 414.

In some demonstrative aspects, the second amplified light 429 may be used as an input Local Oscillator (LO) signal 429 to light detector 418.

In some demonstrative aspects, light detector 418 may be configured to use the input LO signal 429, for example, to determine differences between the received light 412 and the emitted light 415.

For example, light detector 418 may be configured to use the input LO signal 429, for example, to consider temporal fluctuations of the emitted light 415, for example, to detect and/or discriminate an optical frequency of the received light 412.

In some demonstrative aspects, processor 309 (FIG. 3) may be configured to provide detection information, for example, including one or more of range, speed, direction, and/or any other information with respect to one or more targets, for example, by processing the received light 412 and the LO signal 429.

In some demonstrative aspects, one or more components of DAC 402 may be configured to provide a technical solution to support improved DAC performance, for example, in terms of high speed and/or high resolution, e.g., as described below.

In some demonstrative aspects, one or more components of DAC 402 may be configured to provide a technical solution to support improved DAC performance, for example, for laser-based applications and/or any other suitable applications, e.g., as described below.

In some demonstrative aspects, one or more components of DAC 402 may be configured to provide a technical solution to support improved DAC performance, for example, for light-based sensor 400 and/or any other application, e.g., as described below.

In some demonstrative aspects, a laser linewidth of light-based sensor 400 may have an impact, e.g., a relatively high impact, on a LiDAR maximal range supported by the light-based sensor 400. For example, the laser linewidth of light-based sensor 400 may be affected by the driving signal 405 provided by the laser driver 404, while the driving signal 405 provided by the laser deriver 404 may be affected by the analog signal 403 provided by the DAC 402.

In some demonstrative aspects, one or more components of DAC 402 may be configured to provide a technical solution to support a relatively low output noise, for example, a relatively low noise level of the analog signal 403 provided by the DAC 402, e.g., as described below.

In some demonstrative aspects, one or more components of DAC 402 may be configured to provide a technical solution to maintain relatively low, e.g., state of the art, low frequency noise components.

In some demonstrative aspects, one or more components of DAC 402 may be configured to provide a technical solution to support a DAC with very low noise, e.g., ultra-low noise, and/or high resolution, e.g., as described below.

In some demonstrative aspects, DAC 402 may include a current-steering DAC, e.g., as described below.

In some demonstrative aspects, the current-steering DAC may be configured to convert a digital signal into an analog signal including a current signal, e.g., as described below.

In some demonstrative aspects, the current-steering DAC may include a thermometer-decoded current-steering DAC, e.g., as described below.

In some demonstrative aspects, the current-steering DAC may be implemented by a segmented DAC, e.g., as described below.

In some demonstrative aspects, the segmented DAC may include a thermometer-decoded current-steering DAC and a binary current-steering DAC, e.g., as described below.

In some demonstrative aspects, the segmented DAC may include the thermometer-decoded current-steering DAC and any other additional or alternative suitable type of current-steering DAC.

In other aspects, DAC 402 may include a non-segmented DAC, for example, including a thermometer-decoded current-steering DAC, e.g., as described below.

In other aspects, DAC 402 may include any other suitable type of DAC.

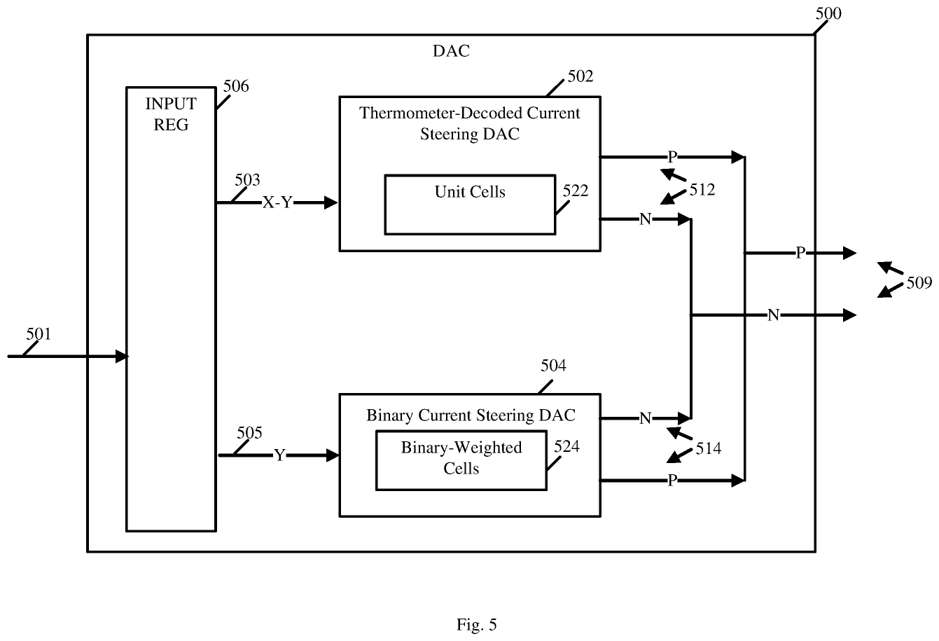

Reference is made to FIG. 5, which schematically illustrates a DAC 500, in accordance with some demonstrative aspects.

In some demonstrative aspects, as shown in FIG. 5, DAC 500 may be configured to convert a digital signal 501 into an analog signal 509.

In some demonstrative aspects, one or more components of DAC 500 may be implemented as part of a LiDAR device. For example, DAC 402 (FIG. 4) may include one or more elements of DAC 500, and/or may be configured to perform one more operations and/or functionalities of DAC 500.

In one example, DAC 500 may be configured to provide analog signal 509 to laser driver 404 (FIG. 4), which may be configured to generate the laser driving signal 405 (FIG. 4), for example, based on the analog signal 509. For example, digital signal 501 may include digital input signal 401 (FIG. 1), and/or analog signal 403 (FIG. 4) may include analog signal 509.

In some demonstrative aspects, DAC 500 may be implemented as part of any other suitable device and/or system.

For example, in some demonstrative aspects, DAC 500 may be implemented as part of a device, for example, an electronic device, a computing device, an audio device, a radar device, a wireless communication device, and/or any other device, for example, to convert digital signals into analog signals.

In some demonstrative aspects, as shown in FIG. 5, DAC 500 may include a segmented current-steering DAC, e.g., as described below.

In some demonstrative aspects, as shown in FIG. 5, segmented current-steering DAC 500 may include a thermometer-decoded current-steering DAC 502, and a binary current-steering DAC 504, e.g., as described below.

In some demonstrative aspects, as shown in FIG. 5, thermometer-decoded current-steering DAC 502 may be configured to generate a first differential signal 512, for example, based on a first subset of bits 503 of the digital signal 501, e.g., as described below.

In some demonstrative aspects, as shown in FIG. 5, binary current-steering DAC 504 may be configured to generate a second differential signal 514, for example, based on a second subset of bits 505 of the digital signal 501, e.g., as described below.

In some demonstrative aspects, as shown in FIG. 5, analog signal 509 may be based on first differential signal 512 and second differential signal 514. For example, analog signal 509 may include a differential signal including a sum of first differential signal 512 and second differential signal 514, e.g., as described below.

In some demonstrative aspects, the first subset of bits 503 may include Most Significant Bits (MSBs) of the digital signal 501, e.g., as described below.

In some demonstrative aspects, the second subset of bits 505 may include Least Significant Bits (LSBs) of the digital signal 501, e.g., as described below.

For example, the digital signal 501 may include a plurality of bits, e.g., including X bits. For example, the second subset of bits 505 may include a plurality of MSBs of the X bits, e.g., including Y MSBs of the X bits. For example, the first subset of bits 503 may include a plurality of LSBs of the X bits, e.g., including (X-Y) LSBs of the X bits.

In some demonstrative aspects, thermometer-decoded current-steering DAC 502 may include a plurality of unit cells 522, which may be controllable, for example, based on the first subset of bits 503, e.g., as described below.

In some demonstrative aspects, binary current-steering DAC 504 may include an array of binary-weighted current-steering cells 524, which may be controllable, for example, based on the second subset of bits 505.

In some demonstrative aspects, one or more components of DAC 500, e.g., thermometer-decoded current-steering DAC 502, may be configured to provide a technical solution to support improved DAC performance, e.g., as described below.

In some demonstrative aspects, one or more components of DAC 500, e.g., thermometer-decoded current-steering DAC 502, may be configured to provide a technical solution to support improved DAC performance, for example, in terms of high DAC speed and/or high DAC resolution, e.g., as described below.

In some demonstrative aspects, one or more components of DAC 500, e.g., thermometer-decoded current-steering DAC 502, may be configured to provide a technical solution to support a DAC resolution of at least 6 bits, for example, a DAC resolution of at least 8 bits, for example, at least 12 bits, e.g., as described below.

In some demonstrative aspects, one or more components of DAC 500, e.g., thermometer-decoded current-steering DAC 502, may be configured to provide a technical solution to support improved DAC performance, for example, for laser-based applications, e.g., as described below.

In some demonstrative aspects, one or more components of DAC 500, e.g., thermometer-decoded current-steering DAC 502, may be configured to provide a technical solution to support improved DAC performance, for example, for a LiDAR device, e.g., as described below.

In some demonstrative aspects, thermometer-decoded current-steering DAC 502 may be configured according to a current-steering architecture, which may utilize a plurality of unit cells (also referred to as current-steering cells), e.g., as described below.

For example, a unit cell, e.g., each unit cell, of a thermometer-decoded current-steering DAC, e.g., thermometer-decoded current-steering DAC 502, may be configured to drive a current, e.g., a substantially fixed current, which may be steered to a first output or a second output, for example, based on a DAC input digital code.

In one example, the first current output may include a positive current output, and the second output may include a negative current output, for example, in a differential output DAC implementation.

For example, as shown in FIG. 5, an output signal of the thermometer-decoded current-steering DAC 502 may include a differential current output, e.g., including the positive current output and the negative current output.

In some demonstrative aspects, for example, in some use cases, scenarios, and/or implementations, there may be one or more technical issues, for example, in a current-steering DAC implementation based on 2-way-steering unit cells, e.g., as described below.

For example, a 2-way-steering unit cell, e.g., each 2-way-steering unit cell, may drive a fixed current, which may be steered by a cell to one of two possible directions, e.g., based on a DAC input digital code. For example, the two directions may include the positive current output and the negative current output, for example, for a differential output DAC implementation.

In one example, a current-steering DAC implementation based on 2-way-steering unit cells may use a large area, e.g., most of an area of the current-steering DAC, which may be devoted to a thermometer-decoded array including the 2-way-steering unit cells, e.g., to maintain linearity of the current-steering DAC. For example, the 2-way-steering unit cells may be arranged as a two-dimensional (2D) array, for example, to support a high resolution DAC, e.g., for a digital signal including 6 bits or more, for example, 12 bits or more.

In one example, in such a 2D implementation of 2-way-steering unit cells, a 2-way-steering unit cell, e.g., each 2-way-steering unit cell, may include at least one current source transistor and one or more current-steering switches, which may be controlled by logical signals provided to the-way-steering unit cell. According to this example, the area of the 2D array may be dominated by routing lines to route the logical signals to each of the 2-way-steering unit cells.

In another example, a 2-way-steering unit cell, e.g., each 2-way-steering unit cell, may be required to include digital logic, which may be used to drive the current-steering switches. According to this example, the digital logic of the 2-way-steering unit cells in the array may operate in a synchronous manner, for example, to avoid switching artefacts. For example, a clock signal may be routed across the 2D array, e.g., to every 2-way-steering unit cell of the 2D array, for example, in order to maintain the synchronous operation.

For example, the implementation of the digital logic, the logical signal routing, the clock signal routing and/or the digital-analog spacing may “waste” array core area, which may result in less area being available for implementation of the unit cells.

For example, the implementation of the digital logic, the logical signal routing, the clock signal routing may result in coupling between the fast-toggling digital signals, the clock signals, and quiescent analog current sources, which, may cause artifacts in the output DAC signal.

For example, implementation of the current-steering DAC implementation utilizing the 2-way-steering unit cells may result in a very large 2D array.

For example, the current-steering DAC implementation utilizing the 2-way-steering unit cell may use a large area devoted to routing, may suffer bad matching between cells, and/or may require balancing a clock distribution across the entire 2D array.

For example, the current-steering DAC implementation utilizing the 2-way-steering unit cell may suffer from large digital-analog coupling, which may potentially add distortion and/or noise to the output DAC signal.

In some demonstrative aspects, thermometer-decoded current-steering DAC 502 may be configured to implement a thermometer-decoded current-steering topology, which may be configured to provide a technical solution to utilize digital circuitry, for example, for current-steering switches, while excluding other digital circuitry from within the analog unit cells, e.g., as described below.

In some demonstrative aspects, the thermometer-decoded current-steering topology may be configured to provide a technical solution to support conversion of a digital signal including six or more bits, for example, 8 or more bits, e.g., as described below.

In some demonstrative aspects, the thermometer-decoded current-steering topology may be configured to provide a technical solution to support a DAC implementation with a reduced chip area, for example, with minimal digital logic, e.g., as described below.

In some demonstrative aspects, the thermometer-decoded current-steering topology may utilize current-steering switches, which may be segmented, for example, into two current-steering switch hierarchies, e.g., as described below.

In some demonstrative aspects, the segmentation of the current-steering switches into the two current-steering switch hierarchies may provide a technical solution, for example, to obviate implementation of in-cell logic, e.g., as described below.

In some demonstrative aspects, a first hierarchy of the two current-steering switch hierarchies may relate to a first dimension of a 2D array, e.g., rows of the 2D array.

In some demonstrative aspects, a second hierarchy of the two current-steering switch hierarchies may relate to a second dimension of the 2D array, e.g., columns of the 2D array.

In other aspects, the first hierarchy may relate to the columns of the 2D array, and/or the second hierarchy may relate to the rows of the 2D array.

In some demonstrative aspects, the first current-steering switch hierarchy may include row-level switches, which may be configured, for example, to steer currents of full rows of the 2D array. For example, the current-steering switches of the first hierarchy may be configured to steer the currents from the full rows of the 2D array, for example, according to MSBs of a digital input signal, e.g., as described below.

In some demonstrative aspects, the second current-steering switch hierarchy may include column-level switches, which may be configured, for example, to steer currents from a particular row, e.g., for selectively steering currents of one or more single cells of the particular row. For example, the current-steering switches of the second current-steering switch hierarchy may be configured to steer the currents from the particular row, for example, according to less significant bits, e.g., LSBs, of the digital input signal, e.g., as described below.

In some demonstrative aspects, the current-steering switches of the first hierarchy may be implemented using 3-way-steering unit cells, e.g., as described below.

In some demonstrative aspects, a 3-way-steering unit cell may be switchable between a first steering state, a second steering state and a third steering state, e.g., as described below.

In some demonstrative aspects, the 3-way-steering unit cell may be switched to the first steering state, for example, to steer current from the 3-way-steering unit cell to a first current path, e.g., as described below.

In some demonstrative aspects, the 3-way-steering unit cell may be switched to the second steering state, for example, to steer the current from the 3-way-steering unit cell to a second current path, e.g., as described below.

In some demonstrative aspects, the 3-way-steering unit cell may be switched to the third steering state, for example, to steer the current from the 3-way-steering unit cell to a switch path, e.g., as described below.

In some demonstrative aspects, the current-steering switches of the second hierarchy may be configured to steer the current from the switch path, for example, to the first current path or the second current path, e.g., as described below.

In some demonstrative aspects, the thermometer-decoded current-steering topology may be configured to provide a technical solution to support implementation of a 2D array of current switching cells, which may be controllable by three control lines per current switching cells of the first hierarchy, e.g., three control lines per row of current switching cells, e.g., to control switching of the 3-way-steering unit cells between the first, second, and third steering states.

In some demonstrative aspects, the thermometer-decoded current-steering topology may be configured to provide a technical solution to support implementation of a 2D array of current switching cells, which may utilize three output current lines per current switching cells of the second hierarchy, for example, three output current lines per column of current switching cells, e.g., as described below.

In some demonstrative aspects, the thermometer-decoded current-steering topology may be configured to provide a technical solution to support a current-steering DAC with relatively low, e.g., very low, noise, high resolution, and/or high performance, for example, with relatively low, e.g., very low, systematic coupling between digital controls and an analog current source array, e.g., as described below.

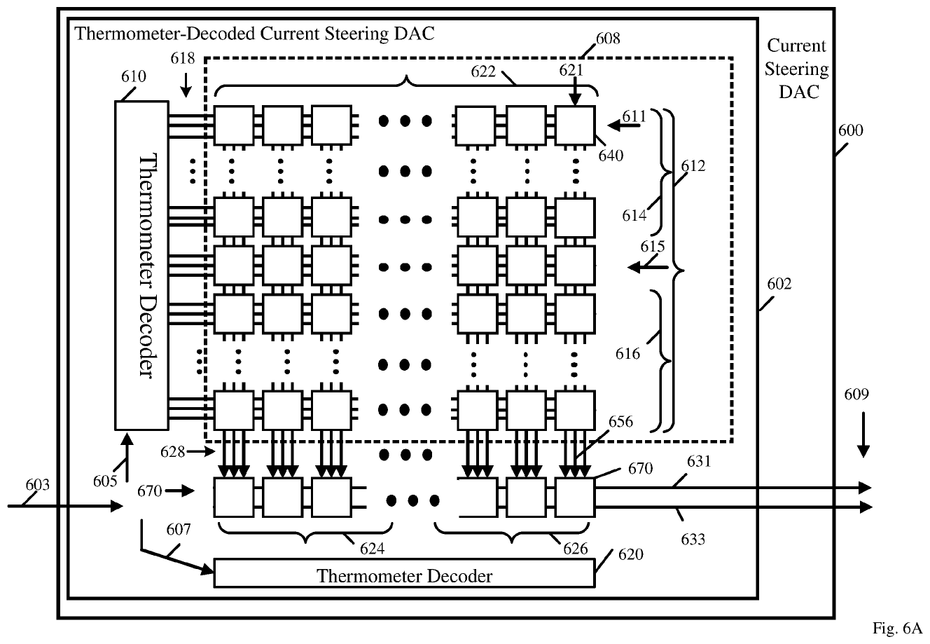

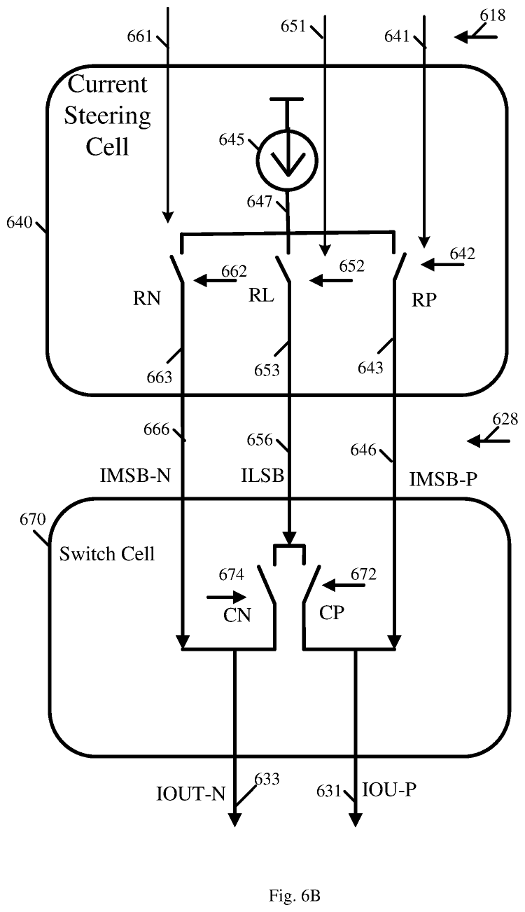

Reference is made to FIG. 6A, which schematically illustrates a current-steering DAC 600, and to FIG. 6B, which schematically illustrates a current-steering cell 640 and a switch cell 670 of the current-steering DAC 600, in accordance with some demonstrative aspects.

In some demonstrative aspects, one or more components of current-steering DAC 600 may be implemented as part of a segmented current-steering DAC. For example, DAC 500 (FIG. 5) may include one or more elements of current-steering DAC 600, and/or may be configured to perform one more operations and/or functionalities of current-steering DAC 600.

In some demonstrative aspects, one or more components of current-steering DAC 600 may be implemented as part of a LiDAR device. For example, DAC 402 (FIG. 4) may include one or more elements of current-steering DAC 600, and/or may be configured to perform one more operations and/or functionalities of current-steering DAC 600.

In some demonstrative aspects, current-steering DAC 600 may be implemented as part of any other suitable device and/or system.

For example, in some demonstrative aspects, current-steering DAC 600 may be implemented as part of a device, for example, an electronic device, a computing device, a radar device, a wireless communication device, and/or any other device, for example, to convert digital signals into analog signals.

In some demonstrative aspects, as shown in FIG. 6A, current-steering DAC 600 may be configured to convert a digital signal 603 into an analog signal 609, e.g., as described below.

In some demonstrative aspects, as shown in FIG. 6A, current-steering DAC 600 may include a thermometer-decoded current-steering DAC 602, e.g., as described below.

For example, thermometer-decoded current-steering DAC 502 (FIG. 5) may include one or more elements of thermometer-decoded current-steering DAC 602, and/or may be configured to perform one more operations and/or functionalities of thermometer-decoded current-steering DAC 602.

In some demonstrative aspects, as shown in FIG. 6A, thermometer-decoded current-steering DAC 602 may include a two-dimensional (2D) array 608 of current-steering cells 640, e.g., as described below.

In some demonstrative aspects, a current-steering cell 640, e.g., each of the current-steering cells 640 in the 2D array 608, may include a unit cell, which may be configured to drive a predefined current unit, e.g., as described below.

In other aspects, a current-steering cell 640, e.g., some or all of the current-steering cells 640 in the 2D array 608, may include any other type of current-steering cell.

In some demonstrative aspects, as shown in FIG. 6A, the 2D array 608 may include a plurality of first-dimension subarrays 612 and a plurality of second-dimension subarrays 622, e.g., as described below.

In one example, shown in FIG. 6A, the plurality of first-dimension subarrays 612 may include a first-dimension subarray 611.

In one example, shown in FIG. 6A, the plurality of second-dimension subarrays 622 may include a second-dimension subarray 621.

In some demonstrative aspects, as shown in FIG. 6A, the plurality of first-dimension subarrays 612 may include a respective plurality of rows of the 2D array 608, e.g., as described below.

In some demonstrative aspects, as shown in FIG. 6A, the plurality of second-dimension subarrays 622 may include a respective plurality of columns of the 2D array 608, e.g., as described below.

In other aspects, the plurality of first-dimension subarrays 612 may include a respective plurality of columns of the 2D array 608, and/or the plurality of second-dimension subarrays 622 may include a respective plurality of rows of the 2D array 608.

In some demonstrative aspects, as shown in FIG. 6B, a current-steering cell 640 of the 2D array 608 may be switchable between a first steering state, a second steering state, and a third steering state, e.g., as described below.

In some demonstrative aspects, as shown in FIG. 6B, the first steering state may be configured to steer a current 647 of the current-steering cell 640 to a first current path 631, e.g., as described below.

In some demonstrative aspects, as shown in FIG. 6B, the second steering state may be configured to steer the current 647 of the current-steering cell 640 to a second current path 633, e.g., as described below.

In some demonstrative aspects, as shown in FIGS. 6A and 6B, the third steering state may be configured to steer the current 647 of the current-steering cell 640 to a switch path 656 of a plurality of switch paths 656 corresponding to the plurality of second-dimension subarrays 622, e.g., as described below.

In some demonstrative aspects, as shown in FIG. 6A, thermometer-decoded current-steering DAC 602 may include a first thermometer decoder 610, which may be configured to generate a first thermometer code based on a first subset of bits 605 of the digital signal 603, e.g., as described below.

In some demonstrative aspects, the first thermometer code may be configured to set the plurality of first-dimension subarrays 612 to a plurality of subarray steering states, respectively, e.g., as described below.

In some demonstrative aspects, as shown in FIG. 6A, thermometer-decoded current-steering DAC 602 may include a plurality of switching cells 670 connected to the plurality of switch paths 656, e.g., as described below.

In some demonstrative aspects, as shown in FIG. 6B, a switching cell 670 connected to the switch path 656 may be switchable between a first switching state, denoted CP, and a second switching state, denoted CN, e.g., as described below.

In some demonstrative aspects, as shown in FIG. 6A, switching cell 670 may be connected to a plurality of current-steering cells 640 of the second-dimension subarray 621.

In some demonstrative aspects, as shown in FIG. 6B, the first switching state of the switching cell 670 may be configured to steer current 647 from the switch path 656 to the first current path 631, e.g., as described below.

In some demonstrative aspects, as shown in FIG. 6B, the second switching state of the switching cell 670 may be configured to steer the current 647 from the switch path 656 to the second current path 633, e.g., as described below.

In some demonstrative aspects, as shown in FIG. 6A, thermometer-decoded current-steering DAC 602 may include a second thermometer decoder 620, which may be configured to generate a second thermometer code, for example, based on a second subset of bits 607 of the digital signal 603, e.g., as described below.

In some demonstrative aspects, the second thermometer code may be configured to control switching states of the plurality of switching cells 670, e.g., as described below.

In some demonstrative aspects, a sum of a count of bits in the first subset of bits 605 and a count of bits in the second subset of bits 607 may be at least 8, e.g., as described below.

In some demonstrative aspects, the sum of the count of bits in the first subset of bits 605 and the count of bits in the second subset of bits 607 may be at least 10, e.g., as described below.

In some demonstrative aspects, the sum of the count of bits in the first subset of bits 605 and the count of bits in the second subset of bits 607 may be at least 12, e.g., as described below.

In some demonstrative aspects, the sum of the count of bits in the first subset of bits 605 and the count of bits in the second subset of bits 607 may be at least 14, e.g., as described below.

In some demonstrative aspects, the sum of the count of bits in the first subset of bits 605 and the count of bits in the second subset of bits 607 may be at least 16, e.g., as described below.

In other aspects, the first subset of bits 605 and/or the second subset of bits 607 may include any other count of bits.

In some demonstrative aspects, the first subset of bits 605 of the digital signal 603 may include MSBs of the digital signal 603, e.g., as described below.

In some demonstrative aspects, the second subset of bits 607 of the digital signal 603 may include less-significant bits, which are less significant than the MSBs of the digital signal 603, e.g., as described below.

In some demonstrative aspects, LSBs of the digital signal 603 may be used as the second subset of bits 505 (FIG. 5), which may be provided to binary current-steering DAC 504 (FIG. 5), for example, to generate the second differential signal 514 (FIG. 5), e.g., as described below.

In other aspects, the second subset of bits 607 of the digital signal 603 may include the of the digital signal 603, e.g., in case the binary current-steering DAC 504 (FIG. 5) is not implemented.

In some demonstrative aspects, the analog signal 609 may be based, for example, on a current in the first current path 631, e.g., as described below.

In some demonstrative aspects, the analog signal 609 may be based, for example, on a current in the second current path 633, e.g., as described below.

In some demonstrative aspects, the analog signal 609 may be based, for example, on the current in the first current path 631 and the current in the second current path 633, e.g., as described below.

In some demonstrative aspects, the analog signal 609 may include a differential signal, e.g., as described below.

In some demonstrative aspects, the differential signal may include a first signal and a second signal, e.g., as described below.

In some demonstrative aspects, the first signal may be based, for example, on a current in the first current path 631, e.g., as described below.

In some demonstrative aspects, the second signal may be based, for example, on a current in the second current path 633, e.g., as described below.

In some demonstrative aspects, the analog signal 609 may include a non-differential signal, e.g., as described below.

In some demonstrative aspects, the analog signal 609 may be based, for example, only on the current in the first current path 631, for example, in case the analog signal 609 includes a non-differential signal, e.g., as described below.

In some demonstrative aspects, the second current path 633 may be grounded, for example, in case the analog signal 609 includes a non-differential signal, e.g., as described below.

In some demonstrative aspects, as shown in FIG. 6A, thermometer-decoded current-steering DAC 602 may include a plurality of sets of control lines 618 to connect the first thermometer decoder 610 to the plurality of first-dimension subarrays 612, e.g., as described below.

In some demonstrative aspects, as shown in FIG. 6A, a set of control lines 618, which may be connected to a first-dimension subarray, e.g., first-dimension subarray 611, may include three control lines, e.g., as described below.

In some demonstrative aspects, as shown in FIG. 6A, the three control lines may be configured to control current-steering cells 640 of the first-dimension subarray 611, for example, according to a subarray steering state for the first-dimension subarray 611, e.g., as described below.

In some demonstrative aspects, as shown in FIG. 6B, the set of control lines 618 may include a first control line 641, a second control line 661, and a third control line 651, e.g., as described below.

In some demonstrative aspects, as shown in FIG. 6B, the current-steering cell 640 may include a first switch 642, which may be controllable by the first control line 641 of the first-dimension subarray 611 including the current-steering cell 640, e.g., as described below.

In some demonstrative aspects, as shown in FIG. 6B, the current-steering cell 640 may include a second switch 662, which may be controllable by the second control line 661 of the first-dimension subarray 611 including the current-steering cell 640, e.g., as described below.

In some demonstrative aspects, as shown in FIG. 6B, the current-steering cell 640 may include a third switch 652, which may be controllable by the third control line 651 of the first-dimension subarray 611 including the current-steering cell 640, e.g., as described below.

In some demonstrative aspects, as shown in FIG. 6B, the first switch 642 may be configured to selectively connect a current source 645 of the current-steering cell 640 to a first steering line 643 of the second-dimension subarray 621 including the current-steering cell 640, e.g., as described below.

In some demonstrative aspects, as shown in FIG. 6B, the second switch 662 may be configured to selectively connect the current source 645 of the current-steering cell 640 to a second steering line 663 of the second-dimension subarray 621 including the current-steering cell 640, e.g., as described below.

In some demonstrative aspects, as shown in FIG. 6B, the third switch 652 may be configured to selectively connect the current source 645 of the current-steering cell 640 to a third steering line 653 of the second-dimension subarray 621 including the current-steering cell 640, e.g., as described below.

In some demonstrative aspects, as shown in FIG. 6A, thermometer-decoded current-steering DAC 602 may include a plurality of sets of steering lines 628, which may be configured to connect the plurality of switching cells 670 to the plurality of second-dimension subarrays 622, e.g., as described below.

In some demonstrative aspects, as shown in FIG. 6A, a set of steering lines 628 may include three steering lines, e.g., as described below.

In some demonstrative aspects, as shown in FIG. 6B, a set of steering lines 628, which may be connected to the second-dimension subarray 621, may include a first steering line 646, a second steering line 666, and a third steering line 656, e.g., as described below.

In some demonstrative aspects, as shown in FIG. 6B, the first steering line 646 may be configured to connect, e.g., via steering line 643, current-steering cells 640 of the second-dimension subarray 621 to the first current path 631, e.g., as described below.

In some demonstrative aspects, as shown in FIG. 6B, the second steering line 666 may be configured to connect, e.g., via steering line 663, current-steering cells 640 of the second-dimension subarray 621 to the second current path 633, e.g., as described below.

In some demonstrative aspects, as shown in FIG. 6B, the third steering line 656 may be configured to connect, e.g., via steering line 653, current-steering cells 640 of the second-dimension subarray 621 to the switch path 656 for the second-dimension subarray 621, e.g., as described below.

In some demonstrative aspects, as shown in FIG. 6B, the switch cell 670 may include a first switch 672 to selectively steer current 647 from the switch path 656 to the first current path 631, e.g., as described below.

In some demonstrative aspects, as shown in FIG. 6B, the switch cell 670 may include a second switch 674 to selectively steer current 647 from the switch path 656 to the second current path 633, e.g., as described below.

In some demonstrative aspects, thermometer decoder 610 may be configured to provide the first thermometer code, which may be configured to set the first-dimension subarray 611 to a subarray steering state for the first-dimension subarray 611, for example, by setting a plurality of current-steering cells 640 in the first-dimension subarray 611 to the subarray steering state for the first-dimension subarray 611, e.g., as described below.

In some demonstrative aspects, thermometer decoder 610 may be configured to provide the first thermometer code, which may be configured to set the first-dimension subarray 611 to a subarray steering state for the first-dimension subarray 611, for example, by collectively setting all current-steering cells 640 in the first-dimension subarray 611 to the subarray steering state for the first-dimension subarray 611, e.g., as described below.

In some demonstrative aspects, thermometer decoder 610 may be configured to provide the first thermometer code, which may be configured to set each first-dimension subarray of the plurality of first-dimension subarrays 612, for example, to either the first steering state, the second steering state, or the third steering state, e.g., as described below.

In some demonstrative aspects, thermometer decoder 610 may be configured to provide the first thermometer code, which may be configured to set no more than one first-dimension subarray of the plurality of first-dimension subarrays 612, e.g., first-dimension subarray 615, to the third steering state, e.g., as described below.

In some demonstrative aspects, as shown in FIG. 6A, thermometer decoder 610 may be configured to set zero or more first-dimension subarrays (“first-state first-dimension subarrays”) 614 to the first steering state, to set zero or more first-dimension subarrays (“second-state first-dimension subarrays”) 616 to the second steering state, and/or to set no more than one first-dimension subarray 615 to the third steering state, e.g., as described below.

In some demonstrative aspects, thermometer decoder 610 may be configured to provide the first thermometer code, which may be configured such that a count of first-state first-dimension subarrays 614, which may be set to the first steering state, may be based, for example, on a value of the first subset of bits 605 of the digital signal 603, e.g., as described below.

In some demonstrative aspects, thermometer decoder 610 may be configured to provide the first thermometer code, which may be configured such that the count of first-state first-dimension subarrays 614, which may be set to the first steering state, may be monotonically increasing, for example, with a value of the first subset of bits 605 of the digital signal 603, e.g., as described below.

In some demonstrative aspects, thermometer decoder 610 may be configured to provide the first thermometer code, which may be configured such that a count of second-state first-dimension subarrays 616, which may be set to the second steering state, may be monotonically decreasing, for example, with the value of the first subset of bits 605 of the digital signal 603, e.g., as described below.

In some demonstrative aspects, as shown in FIG. 6A, thermometer decoder 620 may be configured to set the switching states of the plurality of switching cells 670, for example, by setting zero or more switching cells (“first-state switching cells”) 624 to the first switching state, and setting zero or more switching cells (“second-state switching cells”) 626 to the second switching state, e.g., as described below.

In some demonstrative aspects, thermometer decoder 620 may be configured to provide the second thermometer code, which may be configured such that a count of first-state switching cells 624, which may be set to the first switching state, may be based, for example, on a value of the second subset of bits 607 of the digital signal 603, e.g., as described below.

In some demonstrative aspects, thermometer decoder 620 may be configured to provide the second thermometer code, which may be configured such that the count of first-state switching cells 624, which may be set to the first switching state, may be monotonically increasing, for example, with a value of the second subset of bits 607 of the digital signal 603, e.g., as described below.

In some demonstrative aspects, thermometer decoder 620 may be configured to provide the second thermometer code, which may be configured such that a count of second-state switching cells 626, which may be set to the second switching state, may be monotonically decreasing, for example, with the value of the second subset of bits 607 of the digital signal 603, e.g., as described below.

In some demonstrative aspects, the plurality of first-dimension subarrays 612 may include Nr rows, the plurality of second-dimension subarrays 622 may include Nc columns, and the digital signal 603 may have a value of D.

In some demonstrative aspects, thermometer decoder 610 may be configured to provide the first thermometer code, and/or thermometer decoder 620 may be configured to provide the second thermometer code, for example, such that currents from D current-steering cells 640 may be routed to first current path 631, e.g., a positive output current IOUTp, while current from the rest of the current-steering cells 640 of the 2D array 608, e.g., Nc×Nr-D current-steering cells 640, may be routed to the second current path 633, e.g., a negative output current IOUTn.

In some demonstrative aspects, thermometer decoder 610 may be configured to provide the first thermometer code, and/or thermometer decoder 620 may be configured to provide the second thermometer code, for example, such that the analog signal 609 may include a differential output current, which may increase linearly with the value D.

In some demonstrative aspects, the value D may be separated into a first value (“row count”), denoted Dr, representing a count of rows, e.g., a count of the first-state first-dimension subarrays 614, for example, based on the first subset of bits 605; and a second value (“column count”), denoted Dc, representing a count of columns, e.g., a count of the first-state switching cells 624, for example, based on the second subset of bits 607, e.g., as described below.

For example, the row count value Dr and the column count value Dc may be determined, e.g., as follows:

D=Dr×Nc+Dc,

wherein 0≤Dc<Nc and 0≤Dr<Nr.

In some demonstrative aspects, first thermometer decoder 610 may be configured to generate the first thermometer code to set Dr rows, e.g., the first Dr rows or any other Dr rows, of the 2D array 608, e.g., rows 0 to Dr−1, for example, as the first-state first-dimension subarrays 614, for example, to steer currents from all current-steering cells 640 of the Dr rows to the positive output current IOUTp.

In some demonstrative aspects, first thermometer decoder 610 may be configured to generate the first thermometer code to set Nr-Dr−1 rows, e.g., the last Nr-Dr−1 rows or any other Nr-Dr−1 rows, of the 2D array 608, e.g., rows Dr+1 to Nr−1, for example, as the second-state first-dimension subarrays 616, for example, to steer currents from all current-steering cells 640 of the Nr-Dr−1 rows to the negative output current IOUTn.

In some demonstrative aspects, first thermometer decoder 610 may be configured to generate the first thermometer code to set no more than a single row, denoted Dl, for example, as the first-dimension subarray 615, e.g., to direct currents from all current-steering cells 640 of the single row Dl to the plurality of switching cells 670, e.g., the column switches, for example, rather than directly to the positive output current IOUTp or to the negative output current IOUTn.

In some demonstrative aspects, second thermometer decoder 620 may be configured to generate the second thermometer code, for example, to selectively divert the currents from all current-steering cells 640 of the single row Dl, for example, based on the column value Dc, e.g., as described below.

In some demonstrative aspects, second thermometer decoder 620 may be configured to generate the second thermometer code, for example, to selectively divert the currents from all current-steering cells 640 of the single row Dl between the positive output current IOUTp and the negative output current IOUTn.

In some demonstrative aspects, second thermometer decoder 620 may be configured to generate the second thermometer code, for example, to steer the currents from Dc current-steering cells 640 of the single row Dl to the positive output current IOUTp.

In some demonstrative aspects, second thermometer decoder 620 may be configured to generate the second thermometer code, for example, to steer the currents from the rest of current-steering cells 640 of the single row Dl, e.g., the remaining Nc-Dc current-steering cells 640, to the negative output current IOUTn.

In some demonstrative aspects, as shown in FIG. 6A, first thermometer decoder 610 may be configured to generate the first thermometer code and the second thermometer decoder 620 may be configured to generate the second thermometer code to control the plurality of rows of the 2D array 608 as the plurality of first-dimension subarrays 612, and to control the plurality of columns of the 2D array 608 as the plurality of second-dimension subarrays 622, e.g., as described above.

In other aspects, the roles of the rows and columns may be switched. For example, first thermometer decoder 610 may be configured to generate the first thermometer code and the second thermometer decoder 620 may be configured to generate the second thermometer code to control the plurality of columns of the 2D array 608 as the plurality of first-dimension subarrays 612, and to control the plurality of rows of the 2D array 608 as the plurality of second-dimension subarrays 622.

In some demonstrative aspects, the plurality of first-dimension subarrays 612, e.g., including the first-state first-dimension subarrays 614, the first-dimension subarray 615, and/or the second-state first-dimension subarrays 616, may be arranged in any other physical order.

In some demonstrative aspects, the plurality of second-dimension subarrays 622 may be arranged in any other physical order.

In some demonstrative aspects, the plurality of switching cells 670 including first-state switching cells 624 and second-state switching cells 626 may be arranged in any other physical order.

In one example, first-state first-dimension subarrays 614 may include center rows of 2D array 608. For example, first thermometer decoder 610 may be configured to generate the first thermometer code such that the decoding of the rows may start at or near a center row of 2D array 608.

In another example, first-state switching cells 624 may include one or more center columns of 2D array 608. For example, second thermometer decoder 620 may be configured to generate the second thermometer code such that the decoding of the columns may start at or near a center of 2D array 608.

In another example, first-state first-dimension subarrays 614 may include lower rows of 2D array 608. For example, first thermometer decoder 610 may be configured to generate the first thermometer code such that the decoding of the rows may start from a lower row of 2D array 608.

In another example, first-state switching cells 624 may include right-hand columns of 2D array 608. For example, second thermometer decoder 620 may be configured to generate the second thermometer code such that the decoding of the columns may start from a right-hand side of 2D array 608.

In some demonstrative aspects, current-steering DAC 600 may be configured to utilize a lookup table, which may define a decoding order of the columns and/or a decoding order of the rows of 2D array 608.

In other aspects, the columns and/or rows of 2D array 608 may be decoded according to any other suitable order, scheme and/or data structure.

In some demonstrative aspects, current-steering DAC 600 may be implemented according to a current driving DAC mechanism. For example, P-type Metal Oxide semiconductor (MOS) (PMOS) transistors may be implemented to drive the current of the current-steering cells 640.

In some demonstrative aspects, current-steering DAC 600 may be implemented according to a current-sinking DAC mechanism. For example, N-type MOS (NMOS) transistors may be implemented to pull current from an output of the current-sinking DAC.

In other aspects, current-steering DAC 600 may implement any other additional and/or alternative technique, e.g., other than Complementary MOS (CMOS). For example, current-steering DAC 600 may implement Bipolar Junction Transistor (BJT) transistors, and/or any other type of transistors.

In some demonstrative aspects, the 2D array 608 may include 64 current-steering cells 640, for example, arranged according to an 8×8 arrangement including 8 rows and 8 columns, e.g., as described below.

In some demonstrative aspects, the 2D array 608 may include 8 switching cells 670 arranged as a ninth row of the 2D array 608, e.g., as described below.

In some demonstrative aspects, the first subset of bits 605 and the second subset of bits 607 may be based on a 6-bit code. For example, first thermometer decoder 610 may control the 8 rows of the 2D array 608, for example, based on a first 3-bit code, e.g., including 3 MSBs of the 6-bit code; and/or second thermometer decoder 620 may control the 8 switching cells 670, for example, based on a second 3-bit code, e.g., including 3 LSBs of the 6-bit code, e.g., as described below.

In other aspects, 2D array 608 may include any other count of current-steering cells 640, for example, according to any other arrangement.

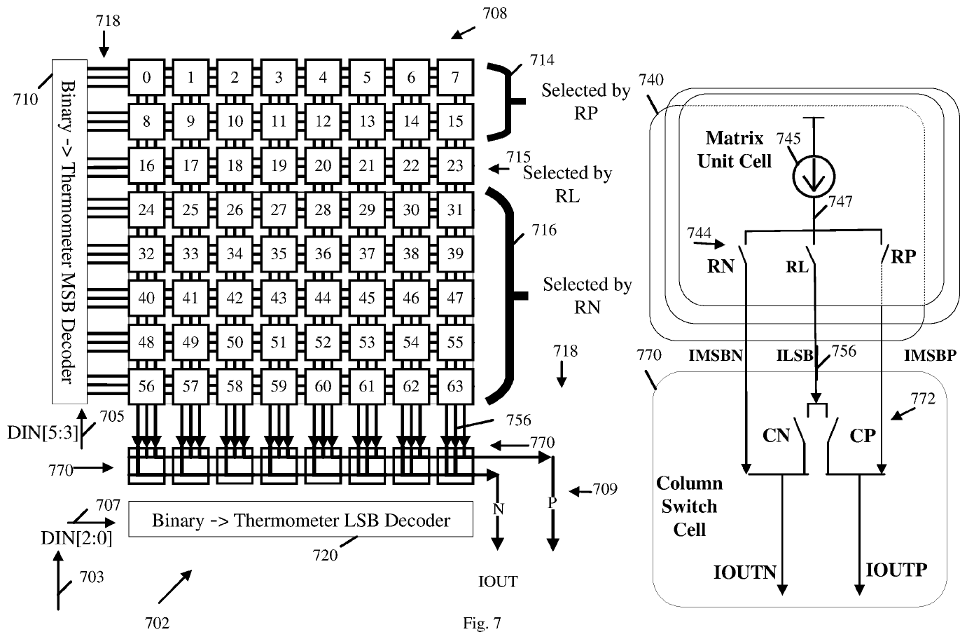

Reference is made to FIG. 7, which schematically illustrates a thermometer-decoded current-steering DAC 702. For example, thermometer-decoded current-steering DAC 602 (FIG. 6) may include one or more elements of thermometer-decoded current-steering DAC 702 and/or may be configured to perform one more operations and/or functionalities of thermometer-decoded current-steering DAC 702.

In some demonstrative aspects, as shown in FIG. 7, thermometer-decoded current-steering DAC 702 may be configured to convert a digital input signal 703 into an analog signal 709 including a differential signal.

In some demonstrative aspects, as shown in FIG. 7, the differential signal may include a positive output current, denoted P, and a negative output current, denoted N.

In some demonstrative aspects, as shown in FIG. 7, thermometer-decoded current-steering DAC 702 may include a 2D array 708 including a plurality of current-steering cells 740, e.g., including 64 current-steering cells 740, denoted 0-63.

In some demonstrative aspects, as shown in FIGS. 7, 2D array 708 may be arranged in an 8×8 arrangement, e.g., including 8 rows and 8 columns.

In some demonstrative aspects, the 64 current-steering cells 740 may be configured to support 64 possible values of a digital input signal 703 including 6 bits.

In other aspects, 2D array 708 may include any other count of current-steering cells 740, e.g., more than 64 current-steering cells 740, which may be arranged in any other arrangement, for example, to support a digital input signal 703 of any other suitable bit-size.

In some demonstrative aspects, as shown in FIG. 7, a current-steering cell 740, e.g., each current-steering cell 740, may include a current source 745 to provide a current 747, which may be steered by a plurality of switches 744.

In some demonstrative aspects, the plurality of switches 744 may be implemented by transistors and/or any other suitable electronic devices.

In some demonstrative aspects, the plurality of switches 744 may be controlled by a plurality of thermometer-decoded control lines 718, e.g., as described below.

In some demonstrative aspects, the plurality of switches 744 may include three switches, e.g., corresponding to three respective steering states.

In some demonstrative aspects, as shown in FIG. 7, the current-steering cell 740 of the 2D array 708 may be switchable between a first steering state, a second steering state, and a third steering state, e.g., as described below.

In some demonstrative aspects, as shown in FIG. 7, a set of control lines 718, which may be shared by steering cells 740 of a full row of the 2D array 708, may include a first control line to control a first switch 744 for the first steering state (RP), a second control line to control a second switch 744 for the second steering state (RN), and a third control line to control a third switch 744 for the third steering state (RL).

In some demonstrative aspects, as shown in FIG. 7, the first steering state RP may be configured to steer the current 747 of the current source 745 to the positive output current.

In some demonstrative aspects, as shown in FIG. 7, the second steering state RN may be configured to steer the current 747 of the current source 745 to the negative output current.

In some demonstrative aspects, as shown in FIG. 7, the third steering state RL may be configured to steer the current 747 of the current source 745 to a switch path 756.

In some demonstrative aspects, thermometer-decoded current-steering DAC 702 may be configured to control the switches 744, for example, such that a current from an additional current source 745 may be added to the positive output current, for example, per increase of a value of the digital input signal 703, e.g., by 1.

In some demonstrative aspects, as shown in FIG. 7, thermometer-decoded current-steering DAC 702 may include a thermometer decoder 710, which may be configured to set the steering states of the steering cells 740 of the 8 rows of the 2D array 708, for example, by the plurality of sets of control lines 718.

In some demonstrative aspects, thermometer decoder 710 may be configured to set the steering states of the steering cells 740 of the 8 rows of the 2D array 708, for example, by collectively setting all current-steering cells 740 in a same row, to a same steering state for the row.

In some demonstrative aspects, thermometer decoder 710 may be configured to set the steering states of the steering cells 740 of the 8 rows of the 2D array 708, for example, by setting the steering cells 740 of a row, e.g., of each row, of the 8 rows, to either the first steering state, the second steering state, or the third steering state.

In some demonstrative aspects, thermometer decoder 710 may be configured to set the steering states of the steering cells 740 of the 8 rows of the 2D array 708, for example, based on a first subset of bits of the digital signal 703.

In some demonstrative aspects, thermometer decoder 710 may be configured to set the steering states of the steering cells 740 of the 8 rows of the 2D array 708, for example, based on 3-MSBbits 705, e.g., bits [5:3], of the digital signal 703.

In some demonstrative aspects, thermometer decoder 710 may be configured to set the steering states of the steering cells 740 of the 8 rows of the 2D array 708, for example, by setting a count of zero or more positive rows (RP rows), which may be set to the first steering state, based on a value of the 3-MSB bits 705 of the digital signal 703. For example, an RP row may include a row that is fully steered to the positive output current.

In some demonstrative aspects, thermometer decoder 710 may be configured to set the steering states of the steering cells 740 of the 8 rows of the 2D array 708, for example, by setting no more than one row (RL row) to the third steering state. For example, the RL row may include the single row that is fully steered to a plurality switching cells 770, for example, via the plurality of switch paths 756.

In some demonstrative aspects, thermometer decoder 710 may be configured to set the steering states of the steering cells 740 of the 8 rows of the 2D array 708, for example, by setting zero or more remaining rows (RN rows) to the second steering state. For example, an RN row may include a row that is fully steered to the negative output current.

In some demonstrative aspects, as shown in FIG. 7, thermometer-decoded current-steering DAC 702 may include a plurality of switching cells 770, e.g., eight switching cells 770, which may be connected to a plurality of switch paths 756.

In some demonstrative aspects, as shown in FIG. 7, the plurality of switch paths 756 may include 8 switch paths, which may correspond to the 8-columns of the 2D array 708.

In some demonstrative aspects, as shown in FIG. 7, a switching cell 770, e.g., each switching cell 770, may be connected to a plurality of current-steering cells 740 of a respective column of 2D array 708.

In some demonstrative aspects, as shown in FIG. 7, a switching cell 770, e.g., connected to the switch path 756, may be switchable between a first switching state, denoted CP, and a second switching state, denoted CN.

In some demonstrative aspects, as shown in FIG. 7, the first switching state CP may be configured to steer current 747 from the switch path 756 to the positive output current.

In some demonstrative aspects, as shown in FIG. 7, the second switching state CN may be configured to steer the current 747 from the switch path 756 to the negative output current.

In some demonstrative aspects, as shown in FIG. 7, the plurality of switch paths 756 may be connected to the RL row, for example, once the RL row is steered to the third switching state.

In some demonstrative aspects, as shown in FIG. 7, thermometer-decoded current-steering DAC 702 may include a second thermometer decoder 720, which may be configured to control the switching states of the plurality of switching cells 770, for example, based on a second subset of bits 707 of the digital signal 703.

For example, second thermometer decoder 720 may include a column decoder, e.g., including a thermometer decoder.

In some demonstrative aspects, second thermometer decoder 720 may be configured to control the switching states of the plurality of switching cells 770, for example, based on a value of the second subset of bits 707, e.g., bits [2:0], for example, the remaining less-significant bits, of the digital signal 703.

In one example, as shown in FIG. 7, second thermometer decoder 720 may be configured to control a plurality of column switches 772, e.g., by a first output line and a second output line of the second thermometer decoder 720 (not shown in FIG. 7).

In some demonstrative aspects, the first output line may control the switch 772 for the first switching state CP, and the second output line may control the switch 772 for the second switching state CN.

In some demonstrative aspects, second thermometer decoder 720 may be configured to control the switching states of the plurality of switching cells 770, for example, to divide currents from the RL row 715, e.g., between the positive current output and the negative current output.

In some demonstrative aspects, second thermometer decoder 720 may be configured to control the switching states of the plurality of switching cells 770, for example, by setting a count of positive switching cells corresponding to positive current-steering cells in the RL row, for example, based on the value of the 3-LSB bits 707 of the digital signal 703.

In some demonstrative aspects, second thermometer decoder 720 may be configured to control the switching states of the plurality of switching cells 770, for example, by setting the remaining switching cells, e.g., negative switching cells corresponding to negative current-steering cells in the RL row, for example, based on the value of the 3-LSB bits of the digital signal 703.

In one example, as shown in FIG. 7, the digital signal 703 may have a value of 21(010101 ). For example, a value of the 3-LSB bits 705 of the digital signal 703 may be 2 (010), and a value of the 3-LSB bits 707 of the digital signal 703 may be 5 (101).

For example, thermometer decoder 710 may be configured to set the row steering states of the 8 rows of the plurality of first-dimension subarrays, for example, by setting 2 full rows 714, e.g., including 16 current-steering cells 740, to steer current to the positive output current; by setting only one row, for example, a full row 715, e.g., including 8 current-steering cells 740, to steer current to the plurality of switch paths 756; and by setting the remaining rows 716, e.g., including 5 last rows, to steer current to the negative output current.

For example, thermometer decoder 720 may be configured to set the steering states of the plurality of switching cells 770, for example, by setting 5 switching cells 770, e.g., corresponding to the current-steering cells 16-20, to steer the current from the 5 corresponding switch paths 756 to the positive output current; and by setting the remaining switching cells 770, e.g., 3 switching cells corresponding to the current-steering cells 21-23, to steer the current from the 3 corresponding switch paths 756 to the negative output current.

According to this example, thermometer-decoded current-steering DAC 702 may be configured to steer current from 21 current-steering cells 740 to the positive current output, for example, by steering current from 2 full rows 714, e.g., including 16 current-steering cells 740, to the positive current output, and by steering the current from the 5 current-steering cells 740 in the RP row 715 to the positive current output.

According to this example, thermometer-decoded current-steering DAC 702 may be configured to steer current from 43 current-steering cells 740 to the negative current output, for example, by steering current from 5 full rows 716, e.g., including 40 current-steering cells 740, to the negative current output, and by steering the current from the 3 current-steering cells 740 in the RP row 715 to the negative current output.

For example, as shown in FIG. 7, based on the input code having a value of 21, current outputs of 21 current-steering cells 740, e.g., including 2 full rows plus 5 more current-steering cells 740 from the RP row, may be steered to the positive output current, and the remaining outputs of the current-steering cells 740, e.g., current outputs of 43 remaining current-steering cells 740, may be steered to the negative output current. For example, the 43 remaining current outputs of the current-steering cells 740 may include current outputs of 5 full rows and 3 current-steering cells 740 from the RP row.

For example, the first two rows [1:0] may be fully selected by the RP line to be outputted as the positive output current, while the last 5 rows [7: 3] may be fully selected by the RN line to be outputted as negative output current, and the third row may be fully selected by the RL line to be outputted via the switching cells 770, which may divide currents of the third row between the negative output current and the positive output current.

In another example (not shown in FIG. 7) the digital signal 703 may have a value of 42 (101010 ). For example, a value of the 3-LSB bits 705 of the digital signal 703 may be 5 (101), and a value of the 3-LSB bits 707 of the digital signal 703 may be 2 (010).

According to this example, thermometer decoder 710 may be configured to set the row steering states of the 8 rows of the plurality of first-dimension subarrays, for example, by setting 5 full rows, e.g., first five rows including current-steering cells 0-39, to steer current to the positive output current; by setting only one row, e.g., the full sixth row including current-steering cells 40-47, to steer current to the plurality of switch paths 756; and by setting the remaining rows, e.g., including the last two rows including current-steering cells 48-63, to steer current to the negative output current.

According to this example, thermometer decoder 720 may be configured to set the steering states of the plurality of switching cells 770, which may be connected to the sixth row, for example, by setting 2 switching cells 770, e.g., corresponding to the current-steering cells 40-41of the sixth row, to steer the current from the 2 corresponding switch paths 756 to the positive output current; and by setting the remaining switching cells 770, e.g., 6 switching cells 770 corresponding to the current-steering cells 42-47 of the sixth row, to steer the current from the 6 corresponding switch paths 756 to the negative output current.

According to this example, thermometer-decoded current-steering DAC 702 may be configured to steer current from 42 current-steering cells 740 to the positive current output, for example, by steering current from 5 full rows, e.g., including 40 current-steering cells 740, to the positive current output, and by steering the current from the 2 current-steering cells 740 in the sixth row to the positive current output.

According to this example, thermometer-decoded current-steering DAC 702 may be configured to steer current from 22 current-steering cells 740 to the negative current output, for example, by steering current from 2 full rows 716, e.g., including 16 current-steering cells 740, to the negative current output, and by steering the current from the 6 current-steering cells 740 in the sixth row to the negative current output.

In another example (not shown in FIG. 7) the digital signal 703 may have a value of 6 (000110). For example, a value of the 3-LSB bits 705 of the digital signal 703 may be 0 (000), and a value of the 3-LSB bits 707 of the digital signal 703 may be 6 (110).

For example, thermometer decoder 710 may be configured to set the row steering states of the 8 rows of the plurality of first-dimension subarrays, for example, by setting only one row, e.g., the first row including current-steering cells 0-7, to steer current to the plurality of switch paths 756; and by setting the remaining rows, e.g., including the last seven rows including current-steering cells 8-63, to steer current to the negative output current.

For example, thermometer decoder 720 may be configured to set the steering states of the plurality of switching cells 770, which may be connected to the first row, for example, by setting 6 switching cells 770, e.g., corresponding to current-steering cells 0-5 of the first row, to steer the current from the 6 corresponding switch paths 756 to the positive output current; and by setting the remaining switching cells 770, e.g., 2 switching cells 770 corresponding to the current-steering cells 6-7 of the first row, to steer the current from the 6 corresponding switch paths 756 to the negative output current.

According to this example, thermometer-decoded current-steering DAC 702 may be configured to steer current from 6 current-steering cells 740 to the positive current output, for example, by steering current from 6 current-steering cells 740 in the first row to the positive current output.

According to this example, thermometer-decoded current-steering DAC 702 may be configured to steer current from 58 current-steering cells 740 to the negative current output, for example, by steering current from 7 full rows, e.g., including 56 current-steering cells 740, to the negative current output, and by steering the current from the 2 current-steering cells 740 in the first row to the negative current output.

In another example (not shown in FIG. 7), the digital signal 703 may have a value of 59(111011 ). For example, a value of the 3-LSB bits 705 of the digital signal 703 may be 7(111), and a value of the 3-LSB bits 707 of the digital signal 703 may be 3(011).

For example, thermometer decoder 710 may be configured to set the row steering states of the 8 rows of the plurality of first-dimension subarrays to the plurality of row steering states, for example, by setting full 7 rows, e.g., including the first seven rows including current-steering cells 0-55, to steer current to the positive output current; and by setting only one row, e.g., the full eighth row including current-steering cells 56-63, to steer current to the plurality of switch paths 756.

For example, thermometer decoder 720 may be configured to set the steering states of the plurality of switching cells 770, which may be connected to the eighth row, for example, by setting 3 switching cells 770, e.g., corresponding to current-steering cells 56-58 of the eighth row, to steer the current from the 3 corresponding switch paths 756 to the positive output current; and by setting the remaining switching cells 770, e.g., 5 switching cells 770 corresponding to current-steering cells 59-63 of the eighth row, to steer the current from the 5 corresponding switch paths 756 to the negative output current.

According to this example, thermometer-decoded current-steering DAC 702 may be configured to steer current from 59 current-steering cells 740 to the positive current output, for example, by steering current from seven full rows, e.g., including 56 current-steering cells 740, to the positive current output, and by steering the current from the 3 current-steering cells 740 in the eighth row to the positive current output.

According to this example, thermometer-decoded current-steering DAC 702 may be configured to steer current from 5 current-steering cells 740 to the negative current output, for example, by steering the current from the 5 current-steering cells 740 in the eighth row to the negative current output.

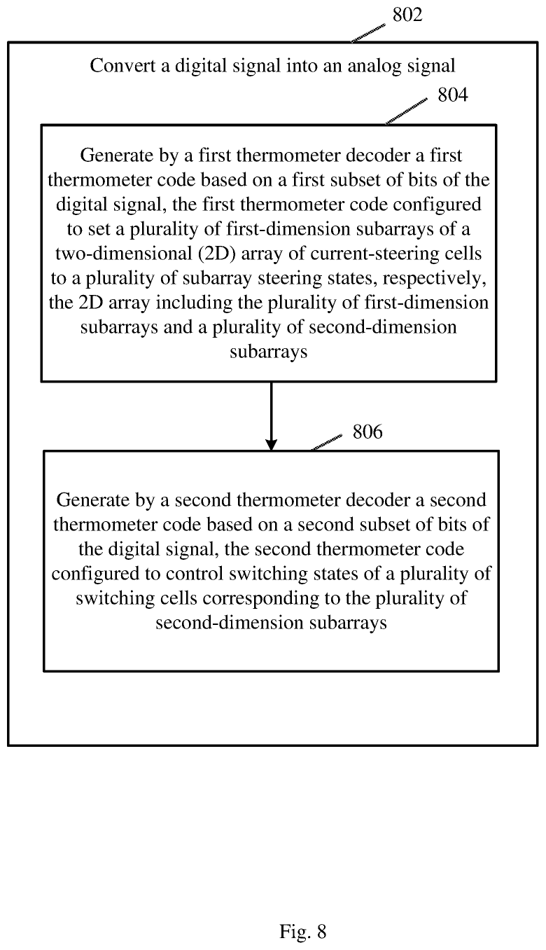

Reference is made to FIG. 8, which schematically illustrates a method of converting a digital signal into an analog signal. For example, one or more of the operations of the method of FIG. 8 may be performed a DAC, e.g., DAC 402 (FIG. 4), DAC 500 (FIG. 5), and/or DAC 600 (FIG. 6), and/or a thermometer-decoded current-steering DAC, e.g., thermometer-decoded current-steering DAC 502 (FIG. 5), thermometer-decoded current-steering DAC 602 (FIG. 6), and/or thermometer-decoded current-steering DAC 802 (FIG. 8).

As indicated at block 802, the method may include converting a digital signal into an analog signal. For example, DAC 600 (FIG. 6) may be configured to convert the digital signal 603 (FIG. 6) into analog signal 609 (FIG. 6), e.g., as described above.

As indicated at block 804, converting the digital signal into the analog signal may include generating by a first thermometer decoder a first thermometer code based on a first subset of bits of the digital signal. For example, the first thermometer code may be configured to set a plurality of first-dimension subarrays of a 2D array of current-steering cells to a plurality of subarray steering states, respectively. For example, the 2D array may include the plurality of first-dimension subarrays and a plurality of second-dimension subarrays. For example, first thermometer decoder 610 (FIG. 6) may be configured to generate the first thermometer code, for example, based on the first subset of bits 605 (FIG. 6) of the digital signal 603 (FIG. 6), e.g., as described above.

As indicated at block 806, converting the digital signal into the analog signal may include generating by a second thermometer decoder a second thermometer code based on a second subset of bits of the digital signal. For example, the second thermometer code may be configured to control switching states of a plurality of switching cells corresponding to the plurality of second-dimension subarrays. For example, second thermometer decoder 620 (FIG. 6) may be configured to generate the second thermometer code, for example, based on the second subset of bits 607 (FIG. 6) of the digital signal 603 (FIG. 6), e.g., as described above.

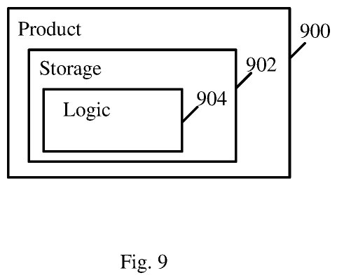

Reference is made to FIG. 9, which schematically illustrates a product of manufacture 900, in accordance with some exemplary aspects. Product 900 may include one or more tangible computer-readable (“machine-readable”) non-transitory storage media 902, which may include computer-executable instructions, e.g., implemented by logic 904, operable to, when executed by at least one computer processor, enable the at least one computer processor to implement one or more operations at a light-based sensor device, e.g., light-based sensor device 101 (FIG. 1), light-based sensor device 300 (FIG. 3), light-based sensor device 211 (FIG. 2), light-based sensor device 400 (FIG. 4), a DAC, e.g., DAC 402 (FIG. 4), DAC 500 (FIG. 5), and/or DAC 600 (FIG. 6), and/or a thermometer-decoded current-steering DAC, e.g., thermometer-decoded current-steering DAC 502 (FIG. 5), thermometer-decoded current-steering DAC 602 (FIG. 6), and/or thermometer-decoded current-steering DAC 702 (FIG. 7); to cause a light-based sensor device, e.g., light-based sensor device 101 (FIG. 1), light-based sensor device 300 (FIG. 3), light-based sensor device 211 (FIG. 2), light-based sensor device 400 (FIG. 4), a DAC, e.g., DAC 402 (FIG. 4), DAC 500 (FIG. 5), and/or DAC 600 (FIG. 6), and/or a thermometer-decoded current-steering DAC, e.g., thermometer-decoded current-steering DAC 502 (FIG. 5), thermometer-decoded current-steering DAC 602 (FIG. 6), and/or thermometer-decoded current-steering DAC 702 (FIG. 7), to perform, trigger and/or implement one or more operations and/or functionalities; and/or to perform, trigger and/or implement one or more operations and/or functionalities described with reference to the FIGS. 1-8, and/or one or more operations described herein. The phrases “non-transitory machine-readable medium” and “computer-readable non-transitory storage media” may be directed to include all computer-readable media, with the sole exception being a transitory propagating signal.

In some demonstrative aspects, product 900 and/or machine-readable storage media 902 may include one or more types of computer-readable storage media capable of storing data, including volatile memory, non-volatile memory, removable or non-removable memory, erasable or non-erasable memory, writeable or re-writeable memory, and the like. For example, machine-readable storage media 902 may include, RAM, DRAM, Double-Data-Rate DRAM (DDR-DRAM), SDRAM, static RAM (SRAM), ROM, programmable ROM (PROM), erasable programmable ROM (EPROM), electrically erasable programmable ROM (EEPROM), flash memory (e.g., NOR or NAND flash memory), content addressable memory (CAM), polymer memory, phase-change memory, ferroelectric memory, silicon-oxide-nitride-oxide-silicon (SONOS) memory, a Solid State Drive (SSD), a disk, a drive, and the like. The computer-readable storage media may include any suitable media involved with downloading or transferring a computer program from a remote computer to a requesting computer carried by data signals embodied in a carrier wave or other propagation medium through a communication link, e.g., a modem, radio, or network connection.

In some demonstrative aspects, logic 904 may include instructions, data, and/or code, which, if executed by a machine, may cause the machine to perform a method, process, and/or operations as described herein. The machine may include, for example, any suitable processing platform, computing platform, computing device, processing device, computing system, processing system, computer, processor, or the like, and may be implemented using any suitable combination of hardware, software, firmware, and the like.

In some demonstrative aspects, logic 904 may include, or may be implemented as, software, a software module, an application, a program, a subroutine, instructions, an instruction set, computing code, words, values, symbols, and the like. The instructions may include any suitable type of code, such as source code, compiled code, interpreted code, executable code, static code, dynamic code, and the like. The instructions may be implemented according to a predefined computer language, manner, or syntax, for instructing a processor to perform a certain function. The instructions may be implemented using any suitable high-level, low-level, object-oriented, visual, compiled and/or interpreted programming language.

### EXAMPLES

The following examples pertain to further aspects.

Example 1 includes an apparatus comprising a current-steering Digital to Analog Converter (DAC) to convert a digital signal into an analog signal, the current-steering DAC comprising a thermometer-decoded current-steering DAC comprising a two-dimensional (2D) array of current-steering cells, the 2D array comprising a plurality of first-dimension subarrays and a plurality of second-dimension subarrays, wherein a current-steering cell of the 2D array is switchable between a first steering state to steer a current of the current-steering cell to a first current path, a second steering state to steer the current of the current-steering cell to a second current path, and a third steering state to steer the current of the current-steering cell to a switch path of a plurality of switch paths corresponding to the plurality of second-dimension subarrays; a first thermometer decoder configured to generate a first thermometer code based on a first subset of bits of the digital signal, the first thermometer code configured to set the plurality of first-dimension subarrays to a plurality of subarray steering states, respectively; a plurality of switching cells connected to the plurality of switch paths, wherein a switching cell connected to the switch path is switchable between a first switching state to steer current from the switch path to the first current path, and a second switching state to steer the current from the switch path to the second current path; and a second thermometer decoder configured to generate a second thermometer code based on a second subset of bits of the digital signal, the second thermometer code configured to control switching states of the plurality of switching cells.

Example 2 includes the subject matter of Example 1, and optionally, wherein the first thermometer code is configured to set a first-dimension subarray to a subarray steering state for the first-dimension subarray by setting a plurality of current-steering cells in the first-dimension subarray to the subarray steering state for the first-dimension subarray.

Example 3 includes the subject matter of Example 1 or 2, and optionally, wherein the first thermometer code is configured to set a first-dimension subarray to a subarray steering state for the first-dimension subarray by collectively setting all current-steering cells in the first-dimension subarray to the subarray steering state for the first-dimension subarray.

Example 4 includes the subject matter of any one of Examples 1-3, and optionally, wherein the first thermometer code is configured to set each first-dimension subarray of the plurality of first-dimension subarrays to either the first steering state, the second steering state, or the third steering state.

Example 5 includes the subject matter of any one of Examples 1-4, and optionally, wherein the first thermometer code is configured to set no more than one first-dimension subarray of the plurality of first-dimension subarrays to the third steering state.

Example 6 includes the subject matter of any one of Examples 1-5, and optionally, wherein the first thermometer code is configured such that a count of first-state first-dimension subarrays set to the first steering state is based on a value of the first subset of bits of the digital signal.

Example 7 includes the subject matter of any one of Examples 1-6, and optionally, wherein the first thermometer code is configured such that a count of first-state first-dimension subarrays set to the first steering state is monotonically increasing with a value of the first subset of bits of the digital signal, and a count of second-state first-dimension subarrays set to the second steering state is monotonically decreasing with the value of the first subset of bits of the digital signal.

Example 8 includes the subject matter of any one of Examples 1-7, and optionally, wherein the second thermometer code is configured such that a count of first-state switching cells set to the first switching state is based on a value of the second subset of bits of the digital signal.

Example 9 includes the subject matter of any one of Examples 1-8, and optionally, wherein the second thermometer code is configured such that a count of first-state switching cells set to the first switching state is monotonically increasing with a value of the second subset of bits of the digital signal, and a count of second-state switching cells set to the second switching state is monotonically decreasing with the value of the second subset of bits of the digital signal.

Example 10 includes the subject matter of any one of Examples 1-9, and optionally, wherein the current-steering cell comprises a first switch controllable by a first control line of a first-dimension subarray comprising the current-steering cell, a second switch controllable by a second control line of the first-dimension subarray comprising the current-steering cell, and a third switch controllable by a third control line of the first-dimension subarray comprising the current-steering cell, wherein the first switch is to selectively connect a current source of the current-steering cell to a first steering line of a second-dimension subarray comprising the current-steering cell, the second switch is to selectively connect the current source of the current-steering cell to a second steering line of the second-dimension subarray comprising the current-steering cell, the third switch is to selectively connect the current source of the current-steering cell to a third steering line of the second-dimension subarray comprising the current-steering cell.

Example 11 includes the subject matter of any one of Examples 1-10, and optionally, comprising a plurality of sets of control lines to connect the first thermometer decoder to the plurality of first-dimension subarrays, wherein a set of control lines connected to a first-dimension subarray comprises three control lines to control current-steering cells of the first-dimension subarray according to a subarray steering state for the first-dimension subarray.

Example 12 includes the subject matter of any one of Examples 1-11, and optionally, comprising a plurality of sets of steering lines to connect the plurality of switching cells to the plurality of second-dimension subarrays, wherein a set of steering lines connected to a second-dimension subarray comprises a first steering line to connect current-steering cells of the second-dimension subarray to the first current path, a second steering line to connect the current-steering cells of the second-dimension subarray to the second current path, and a third steering line to connect the current-steering cells of the second-dimension subarray to a switch path for the second-dimension subarray.

Example 13 includes the subject matter of any one of Examples 1-12, and optionally, wherein the analog signal is based on at least one of a current in the first current path or a current in the second current path.

Example 14 includes the subject matter of any one of Examples 1-13, and optionally, wherein the analog signal comprises a differential signal comprising a first signal and a second signal, the first signal based on a current in the first current path, the second signal based on a current in the second current path.

Example 15 includes the subject matter of any one of Examples 1-13, and optionally, wherein the analog signal is based on a current in the first current path, wherein the second current path is grounded.

Example 16 includes the subject matter of any one of Examples 1-15, and optionally, wherein the plurality of first-dimension subarrays comprises a respective plurality of columns of the 2D array, and wherein the plurality of second-dimension subarrays comprises a respective plurality of rows of the 2D array.

Example 17 includes the subject matter of any one of Examples 1-15, and optionally, wherein the plurality of first-dimension subarrays comprises a respective plurality of rows of the 2D array, and wherein the plurality of second-dimension subarrays comprises a respective plurality of columns of the 2D array.

Example 18 includes the subject matter of any one of Examples 1-17, and optionally, wherein the first subset of bits of the digital signal comprises Most Significant Bits (MSBs) of the digital signal, wherein the second subset of bits of the digital signal comprises less-significant bits, which are less significant than the MSBs of the digital signal.

Example 19 includes the subject matter of any one of Examples 1-18, and optionally, wherein the current-steering DAC comprises a segmented DAC comprising the thermometer-decoded current-steering DAC and a binary current-steering DAC, wherein the first subset of bits of the digital signal comprises Most Significant Bits (MSBs) of the digital signal, and the second subset of bits of the digital signal comprises middle bits of the digital signal, wherein the binary current-steering DAC comprises an array of binary-weighted current-steering cells controllable based on Least Significant Bits (LSBs) of the digital signal.

Example 20 includes the subject matter of any one of Examples 1-19, and optionally, wherein a sum of a count of bits in the first subset of bits and a count of bits in the second subset of bits is at least 8.

Example 21 includes the subject matter of any one of Examples 1-20, and optionally, wherein each of the current-steering cells in the 2D array comprises a unit cell configured to drive a predefined current unit.

Example 22 includes the subject matter of any one of Examples 1-21, and optionally, comprising a Light Detection and Ranging (LiDAR) device comprising a controller configured to provide the digital signal, and a laser driver controllable to emit laser light based on the analog signal.

Example 23 includes a Light Detection and Ranging (LiDAR) device comprising a current-steering Digital to Analog Converter (DAC) according to any of examples 1-22.

Example 24 includes a vehicle comprising a current-steering Digital to Analog Converter (DAC) according to any of examples 1-22.

Example 25 includes an apparatus comprising current-steering Digital to Analog Converter (DAC) according to any of examples 1-22.

Example 26 includes a method of a current-steering Digital to Analog Converter (DAC) according to any of examples 1-22.

Functions, operations, components and/or features described herein with reference to one or more aspects, may be combined with, or may be utilized in combination with, one or more other functions, operations, components and/or features described herein with reference to one or more other aspects, or vice versa.

While certain features have been illustrated and described herein, many modifications, substitutions, changes, and equivalents may occur to those skilled in the art. It is, therefore, to be understood that the appended claims are intended to cover all such modifications and changes as fall within the true spirit of the disclosure.

1-23. (canceled)

24. An apparatus comprising:
a current-steering Digital to Analog Converter (DAC) to convert a digital signal into an analog signal, the current-steering DAC comprising a thermometer-decoded current-steering DAC comprising:
a two-dimensional (2D) array of current-steering cells, the 2D array comprising a plurality of first-dimension subarrays and a plurality of second-dimension subarrays, wherein a current-steering cell of the 2D array is switchable between a first steering state to steer a current of the current-steering cell to a first current path, a second steering state to steer the current of the current-steering cell to a second current path, and a third steering state to steer the current of the current-steering cell to a switch path of a plurality of switch paths corresponding to the plurality of second-dimension subarrays;
a first thermometer decoder configured to generate a first thermometer code based on a first subset of bits of the digital signal, the first thermometer code configured to set the plurality of first-dimension subarrays to a plurality of subarray steering states, respectively;
a plurality of switching cells connected to the plurality of switch paths, wherein a switching cell connected to the switch path is switchable between a first switching state to steer current from the switch path to the first current path, and a second switching state to steer the current from the switch path to the second current path; and
a second thermometer decoder configured to generate a second thermometer code based on a second subset of bits of the digital signal, the second thermometer code configured to control switching states of the plurality of switching cells.

25. The apparatus of claim 24, wherein the first thermometer code is configured to set a first-dimension subarray to a subarray steering state for the first-dimension subarray by setting a plurality of current-steering cells in the first-dimension subarray to the subarray steering state for the first-dimension subarray.

26. The apparatus of claim 24, wherein the first thermometer code is configured to set a first-dimension subarray to a subarray steering state for the first-dimension subarray by collectively setting all current-steering cells in the first-dimension subarray to the subarray steering state for the first-dimension subarray.

27. The apparatus of claim 24, wherein the first thermometer code is configured to set each first-dimension subarray of the plurality of first-dimension subarrays to either the first steering state, the second steering state, or the third steering state.

28. The apparatus of claim 24, wherein the first thermometer code is configured to set no more than one first-dimension subarray of the plurality of first-dimension subarrays to the third steering state.

29. The apparatus of claim 24, wherein the first thermometer code is configured such that a count of first-state first-dimension subarrays set to the first steering state is based on a value of the first subset of bits of the digital signal.

30. The apparatus of claim 24, wherein the first thermometer code is configured such that a count of first-state first-dimension subarrays set to the first steering state is monotonically increasing with a value of the first subset of bits of the digital signal, and a count of second-state first-dimension subarrays set to the second steering state is monotonically decreasing with the value of the first subset of bits of the digital signal.

31. The apparatus of claim 24, wherein the second thermometer code is configured such that a count of first-state switching cells set to the first switching state is based on a value of the second subset of bits of the digital signal.

32. The apparatus of claim 24, wherein the second thermometer code is configured such that a count of first-state switching cells set to the first switching state is monotonically increasing with a value of the second subset of bits of the digital signal, and a count of second-state switching cells set to the second switching state is monotonically decreasing with the value of the second subset of bits of the digital signal.

33. The apparatus of claim 24, wherein the current-steering cell comprises a first switch controllable by a first control line of a first-dimension subarray comprising the current-steering cell, a second switch controllable by a second control line of the first-dimension subarray comprising the current-steering cell, and a third switch controllable by a third control line of the first-dimension subarray comprising the current-steering cell, wherein the first switch is to selectively connect a current source of the current-steering cell to a first steering line of a second-dimension subarray comprising the current-steering cell, the second switch is to selectively connect the current source of the current-steering cell to a second steering line of the second-dimension subarray comprising the current-steering cell, the third switch is to selectively connect the current source of the current-steering cell to a third steering line of the second-dimension subarray comprising the current-steering cell.

34. The apparatus of claim 24 comprising a plurality of sets of control lines to connect the first thermometer decoder to the plurality of first-dimension subarrays, wherein a set of control lines connected to a first-dimension subarray comprises three control lines to control current-steering cells of the first-dimension subarray according to a subarray steering state for the first-dimension subarray.

35. The apparatus of claim 24 comprising a plurality of sets of steering lines to connect the plurality of switching cells to the plurality of second-dimension subarrays, wherein a set of steering lines connected to a second-dimension subarray comprises a first steering line to connect current-steering cells of the second-dimension subarray to the first current path, a second steering line to connect the current-steering cells of the second-dimension subarray to the second current path, and a third steering line to connect the current-steering cells of the second-dimension subarray to a switch path for the second-dimension subarray.

36. The apparatus of claim 24, wherein the analog signal is based on at least one of a current in the first current path or a current in the second current path.

37. The apparatus of claim 24, wherein the analog signal comprises a differential signal comprising a first signal and a second signal, the first signal based on a current in the first current path, the second signal based on a current in the second current path.

38. The apparatus of claim 24, wherein the analog signal is based on a current in the first current path, wherein the second current path is grounded.

39. The apparatus of claim 24, wherein the plurality of first-dimension subarrays comprises a respective plurality of columns of the 2D array, and wherein the plurality of second-dimension subarrays comprises a respective plurality of rows of the 2D array.

40. The apparatus of claim 24, wherein the plurality of first-dimension subarrays comprises a respective plurality of rows of the 2D array, and wherein the plurality of second-dimension subarrays comprises a respective plurality of columns of the 2D array.

41. The apparatus of claim 24, wherein the first subset of bits of the digital signal comprises Most Significant Bits (MSBs) of the digital signal, wherein the second subset of bits of the digital signal comprises less-significant bits, which are less significant than the MSBs of the digital signal.

42. The apparatus of claim 24, wherein the current-steering DAC comprises a segmented DAC comprising the thermometer-decoded current-steering DAC and a binary current-steering DAC, wherein the first subset of bits of the digital signal comprises Most Significant Bits (MSBs) of the digital signal, and the second subset of bits of the digital signal comprises middle bits of the digital signal, wherein the binary current-steering DAC comprises an array of binary-weighted current-steering cells controllable based on Least Significant Bits (LSBs) of the digital signal.

43. The apparatus of claim 24, wherein a sum of a count of bits in the first subset of bits and a count of bits in the second subset of bits is at least 8.

44. The apparatus of claim 24, wherein each of the current-steering cells in the 2D array comprises a unit cell configured to drive a predefined current unit.

45. An electronic device comprising:
a processor configured to provide a digital signal; and
a current-steering Digital to Analog Converter (DAC) to convert the digital signal into an analog signal, the current-steering DAC comprising a thermometer-decoded current-steering DAC comprising:
a two-dimensional (2D) array of current-steering cells, the 2D array comprising a plurality of first-dimension subarrays and a plurality of second-dimension subarrays, wherein a current-steering cell of the 2D array is switchable between a first steering state to steer a current of the current-steering cell to a first current path, a second steering state to steer the current of the current-steering cell to a second current path, and a third steering state to steer the current of the current-steering cell to a switch path of a plurality of switch paths corresponding to the plurality of second-dimension subarrays;
a first thermometer decoder configured to generate a first thermometer code based on a first subset of bits of the digital signal, the first thermometer code configured to set the plurality of first-dimension subarrays to a plurality of subarray steering states, respectively;
a plurality of switching cells connected to the plurality of switch paths, wherein a switching cell connected to the switch path is switchable between a first switching state to steer current from the switch path to the first current path, and a second switching state to steer the current from the switch path to the second current path; and
a second thermometer decoder configured to generate a second thermometer code based on a second subset of bits of the digital signal, the second thermometer code configured to control switching states of the plurality of switching cells.

46. The electronic device of claim 45 comprising a plurality of sets of steering lines to connect the plurality of switching cells to the plurality of second-dimension subarrays, wherein a set of steering lines connected to a second-dimension subarray comprises a first steering line to connect current-steering cells of the second-dimension subarray to the first current path, a second steering line to connect the current-steering cells of the second-dimension subarray to the second current path, and a third steering line to connect the current-steering cells of the second-dimension subarray to a switch path for the second-dimension subarray.
